(19) United States
(12) Patent Application Publication
(10) Pub. No.: US 2015/0201499 A1
(43) Pub. Date: Jul. 16, 2015

(54) DEVICE, SYSTEM, AND METHOD OF THREE-DIMENSIONAL PRINTING

(71) Applicants: Zohar SHINAR, Demarest, NJ (US); Joel VIDAL, Tenafly, NJ (US)

(72) Inventors: Zohar SHINAR, Demarest, NJ (US); Joel VIDAL, Tenafly, NJ (US)

(21) Appl. No.: 14/153,071

(22) Filed: Jan. 12, 2014

(51) Int. Cl. H05K 3/12; B29C 67/00

(52) U.S. Cl. CPC H05K 3/125; B29C 67/0066; B29C 67/0088; B29K 2105/0058

(57) ABSTRACT

Device, system, and method of three-dimensional printing. A device includes: a first 3D-printing head to selectively discharge conductive 3D-printing material; a second 3D-printing head to selectively discharge insulating 3D-printing material; and a processor to control operations of the first and second 3D-printing heads based on a computer-aided design (CAD) scheme describing a printed circuit board (PCB) intended for 3D-printing. A 3D-printer device utilizes 3D-printing methods, in order to 3D-print: (a) a functional multi-layer PCB; or (b) a functional stand-alone electric component; or (c) a functional PCB having an embedded or integrated electric component, both of them 3D-printed in a unified 3D-printing process.

### FIELD

Some embodiments relate to the field of three-dimensional printing.

### BACKGROUND

Three-dimensional (3D) printing is a process of making a three-dimensional solid object based on a digital model. For example, an additive process is used, in which successive layers of plastic material are laid down. Three-dimensional printing may be used for prototyping, and is considered a distinct field from the field of injection molding of raw plastic materials.

### SUMMARY

Some embodiments of the present invention may include, for example, devices, systems, and methods of three-dimensional printing. Particularly, some embodiments may utilize 3D-printing to create a functional and fully-operative 3D-printed Printed Circuit Board (PCB), as well as a functional and fully-operative 3D-printed electronic circuit or Integrated Circuit (IC) or electronic component (e.g., a resistor, a capacitor) or related component (e.g., a coaxial component or cable or mesh, a waveguide).

In some embodiments, a device comprises: a first 3D-printing head to selectively discharge conductive 3D-printing material; a second 3D-printing head to selectively discharge insulating 3D-printing material; a processor to control operations of the first and second 3D-printing heads based on a computer-aided design (CAD) scheme describing a multi-layer printed circuit board (PCB) intended for 3D-printing.

In some embodiments, the first and second 3D-printing heads are to 3D-print a functional multi-layer PCB; e.g., having at least two layers, or at least three layers, or at least four layers, or at least five layers, or at least six layers, or at least seven layers, or at least eight layers, or the like.

In some embodiments, the first and second 3D-printing heads are to 3D-print a functional (passive and/or active) electrical component, a functional resistor, a functional capacitor, a functional electromagnetic waveguide, a functional optical waveguide, a functional antenna or protruding antenna or horn antenna, a functional heat sink, a functional coaxial element or coaxial cable or coaxial mesh, or the like.

In some embodiments, the first and second 3D-printing heads are to 3D-print, in a same 3D-printing session, both (A) a PCB, and (B) an electrical component embedded within said PCB.

In some embodiments, the first 3D-printing head is to discharge epoxy impregnated with highly-conductive metallic nano-particles; or to discharge resin impregnated with highly-conductive metallic nano-particles.

In some embodiments, the first 3D-printing head and the second 3D-printing head are implemented as a unified 3D-printing head able to discharge, alternately, the conductive 3D-printing material and the insulating 3D-printing material. In some embodiments, the unified 3D-printing head is automatically cleaned between 3D-printing of insulating material and 3D-printing of conductive material.

In some embodiments, the first 3D-printing head that is able to discharge the conductive 3D-printing material is associated with at least first and second 3D-printing nozzles. The first 3D-printing nozzle is to discharge the conductive 3D-printing material through a first nozzle aperture having a first diameter. The second 3D-printing nozzle is to discharge the conductive 3D-printing material through a second nozzle aperture having a second, different, diameter. In some embodiments, the device comprises: an on-the-fly switching module to selectively activate, during a 3D-printing process, one of the first and second 3D-printing nozzles.

In some embodiments, the device comprises: an ultraviolet (UV) energy based curing module, to emit ultraviolet radiation for curing 3D-printed materials region-by-region as the 3D-printed materials are being 3D-printed.

In some embodiments, the device comprises: an ultraviolet (UV) energy based curing module, to follow the 3D-printing heads and to emit targeted ultraviolet radiation for curing just-dispensed 3D-printed materials.

In some embodiments, the device comprises: a laser source to emit a laser beam for curing 3D-printed materials region-by-region as 3D-printed materials are being 3D-printed.

In some embodiments, the device comprises: a laser source to emit a targeted laser beam; wherein the laser source follows the 3D-printing head(s) and emits the targeted laser beam for curing just-dispensed 3D-printed materials.

In some embodiments, the device comprises: a transition 3D-printing module (A) to 3D-print a first trace of conductive material; (B) to 3D-print, on top a particular spot of the first trace, a bridge formed of an insulating material; (C) to 3D-print, on top of said bridge, a second trace of conductive material.

In some embodiments, the device comprises: a via 3D-printing module to 3D-print a structure that functionally corresponds to an inter-layer via.

In some embodiments, the device comprises: a filled via 3D-printing module to 3D-print a structure that functionally corresponds to an inter-layer filled via which is filled with at least one of: (a) a 3D-printed electrically-conductive material, (b) a 3D-printed thermally-conductive material; wherein the filled via 3D-printing module is to fill at least 85 or 90 or 95 or 98 or 99 percent of a volume of said structure, using 3D-printing, with a 3D-printed material.

In some embodiments, the device comprises: a blind via 3D-printing module to 3D-print, in a drill-free process, a structure that functionally corresponds to an inter-layer blind via having a ratio of via depth to via diameter of at least 25-to-1, or at least 30-to-1, or at least 40-to-1.

In some embodiments, the device comprises: a buried via 3D-printing module to 3D-print, in a drill-free process, a structure that functionally corresponds to an inter-layer buried via having a ratio of via depth to via diameter of at least 25-to-1, or at least 30-to-1, or at least 40-to-1.

In some embodiments, the device comprises: a hollow via 3D-printing module to 3D-print, in a drill-free process, a structure that functionally corresponds to an inter-layer hollow via having a ratio of via depth to via diameter of at least 25-to-1, or at least 30-to-1, or at least 40-to-1.

In some embodiments, the device comprises: a drill-free 3D-printing module to 3D-print, in a drill-free and ablation-free process and without a subtractive process, a multi-layer structure that functionally corresponds to an inter-layer via.

In some embodiments, the device comprises: a non-vertical via 3D-printing module to 3D-print a three-dimensional structure that (A) functionally corresponds to an inter-layer via, and (B) is non-perpendicular relative to at least one layer.

In some embodiments, the device comprises: a non-vertical via 3D-printing module to 3D-print a three-dimensional structure that (A) functionally corresponds to an inter-layer via, and (B) is structured three-dimensionally in a structure selected from the group consisting of: a slanted inter-layer structure, a diagonal inter-layer structure, an inter-layer slope, a curved inter-layer structure, a concave inter-layer structure, a convex inter-layer structure, a stairway-shaped inter-layer structure.

In some embodiments, the device comprises: a via equivalent 3D-printing module to 3D-print a three-dimensional structure that (A) functionally corresponds to an inter-layer via, and (B) comprises a 3D-printed inter-layer transition of trace between layers while maintaining trace width and trace thickness.

In some embodiments, the device comprises: an impedance reference 3D-printing module to 3D-print a dedicated region of 3D-printed material as reference ground for 3D-printed impedance-controlled trace.

In some embodiments, the device comprises: an impedance reference 3D-printing module to 3D-print a dedicated region of 3D-printed material as reference ground for 3D-printed impedance-controlled trace; wherein the 3D-printed reference ground occupies less than an entirety of a horizontal layer of a 3D-printed PCB that comprises said 3D-printed impedance-controlled trace.

In some embodiments, the device comprises: an impedance reference 3D-printing module to 3D-print a dedicated region of 3D-printed material as reference ground for 3D-printed impedance-controlled trace; wherein the 3D-printed reference ground follows the 3D-printed impedance-controlled trace and is 3D-printed over the 3D-printed impedance-controlled trace.

In some embodiments, the device comprises: an impedance reference 3D-printing module to 3D-print a dedicated region of 3D-printed material as reference ground for 3D-printed impedance-controlled trace; wherein the 3D-printed reference ground follows the 3D-printed impedance-controlled trace and is 3D-printed to be under the 3D-printed impedance-controlled trace.

In some embodiments, the device comprises: an impedance reference 3D-printing module to 3D-print a dedicated region of 3D-printed material as reference power for 3D-printed impedance-controlled trace.

In some embodiments, the device comprises: an impedance reference 3D-printing module to 3D-print a dedicated region of 3D-printed material as reference power for 3D-printed impedance-controlled trace; wherein the 3D-printed reference power occupies less than an entirety of a horizontal layer of a 3D-printed PCB that comprises said 3D-printed impedance-controlled trace.

In some embodiments, the device comprises: an impedance reference 3D-printing module to 3D-print a dedicated region of 3D-printed material as reference power for 3D-printed impedance-controlled trace; wherein the 3D-printed reference power follows the 3D-printed impedance-controlled trace and is 3D-printed over the 3D-printed impedance-controlled trace.

In some embodiments, the device comprises: an impedance reference 3D-printing module to 3D-print a dedicated region of 3D-printed material as reference power for 3D-printed impedance-controlled trace; wherein the 3D-printed reference power follows the 3D-printed impedance-controlled trace and is 3D-printed to be under the 3D-printed impedance-controlled trace.

In some embodiments, the device comprises: an on-the-fly Automatic Optical Inspection (AOI) module (A) to capture an image of a 3D-printed conductive trace during an ongoing 3D-printing session; (B) to compare the captured image to a reference indicating a required width of the 3D-printed conductive trace; (C) based on the comparison, to determine that a width of at least a portion of the 3D-printed conductive trace is smaller than the required width; (D) to trigger a corrective 3D-printing operation to increase the width of said portion of the 3D-printed conductive trace.

In some embodiments, the device comprises: an on-the-fly Automatic Optical Inspection (AOI) module (A) to capture an image of a 3D-printed conductive trace during an ongoing 3D-printing session; (B) to compare the captured image to a reference indicating a required width of the 3D-printed conductive trace; (C) based on the comparison, to determine that a width of at least a portion of the 3D-printed conductive trace is greater than the required width; (D) to trigger a laser ablation module to decrease the width of said portion of the 3D-printed conductive trace.

In some embodiments, the device comprises: an on-the-fly Automatic Optical Inspection (AOI) module (A) to capture an image of a 3D-printed conductive trace during an ongoing 3D-printing session; (B) to compare the captured image to a reference indicating a required structure of the 3D-printed conductive trace; (C) based on the comparison, to identify a fracture in the 3D-printed conductive trace; (D) to trigger a corrective 3D-printing operation to 3D-print again, correctly, at least a region comprising said fracture.

In some embodiments, the device comprises: an on-the-fly Automatic Optical Inspection (AOI) module (A) to capture an image of a 3D-printed pad of during an ongoing 3D-printing session of a 3D-printed PCB; (B) to compare the captured image to a reference indicating a required structure of the 3D-printed pad; (C) based on the comparison, to determine that the 3D-printed pad is excessively large; (D) to trigger a laser ablation module to decrease the size of said 3D-printed pad.

In some embodiments, the device comprises: an over-the-top 3D-printing module (A) to identify a first available region on a top surface of a 3D-printed PCB, in proximity to a second region of said top surface which is reserved for Surface-Mount Technology (SMT)/Chip-On-Board (COB) component assembly; (B) to 3D-print a conductive trace at said first available region on said top surface of the 3D-printed PCB.

In some embodiments, the device comprises: a soldermask 3D-printing module to 3D-print a soldermask on a 3D-printed PCB, wherein the soldermask and the PCB are 3D-printed in a single, unified, 3D-printing process.

In some embodiments, the device comprises: a soldermask 3D-printing module to 3D-print a soldermask on a 3D-printed PCB; and a 3D-printing ordering module to cause the device: (A) to 3D-print a first region of the 3D-printed PCB, and (B) to 3D-print soldermask onto said first region of the 3D-printed PCB, and (C) to wait for said soldermask to cure at said first region.

In some embodiments, the device comprises: an insulating filament 3D-printing module to create a soldermask-free 3D-printed PCB by 3D-printing an insulating filament over a top layer of said 3D-printed PCB, and to create 3D-printed insulating separation between two or more 3D-printed conductive pads.

In some embodiments, the device comprises: a horn antenna 3D-printing module to 3D-print a three-dimensional mushroom-shaped horn antenna integrated in a pre-defined region of a 3D-printed PCB being 3D-printed and protruding outwardly from a top layer of the 3D-printed PCB.

In some embodiments, the device comprises: a heat sink 3D-printing module to 3D-print a thermally-conductive heat sink integrated in a pre-defined region of a 3D-printed PCB being 3D-printed.

In some embodiments, the device comprises: a thermal conductivity planner (A) to determine that a particular region of a PCB being 3D-printed, being located under a 3D-printed conductive pad, requires a heat transfer path with increased thermal conductivity; (B) to 3D-print, in a region under said 3D-printed conductive pad, with a first 3D-printing material having increased thermal conductivity relative to a second 3D-printing material used for 3D-printing at a surrounding region which does not require a heat transfer path with increased thermal conductivity.

In some embodiments, the device comprises: a thermal conductivity planner (A) to determine that a particular region of a PCB being 3D-printed requires a heat transfer path with increased thermal conductivity; (B) to 3D-print, at said particular region of the PCB being 3D-printed, an electrically conductive path extending from said particular region downwardly to a 3D-printed heat sink at a bottom portion of said PCB being 3D-printed.

In some embodiments, the device comprises: an embedded COB component 3D-printing module, to 3D-print a 3D-printed PCB having a fully-buried 3D-printed Chip-On-Board (COB) component.

In some embodiments, the device comprises: an embedded SMT component 3D-printing module, to 3D-print a 3D-printed PCB having a fully-buried (unexposed) 3D-printed Surface-Mount Technology (SMT) component.

In some embodiments, the device comprises: a pause-and-resume 3D-printing controller, (A) to pause a 3D-printing process of a PCB being 3D-printed, and (B) to wait until a COB/SMT component is assembled onto an already-3D-printed portion of the PCB, and (C) to resume the 3D-printing process of said PCB on top of the COB/SMT that was 3D-printed.

In some embodiments, the device comprises: an on-the-fly trace width/thickness modifier to modify, during a 3D-printing process of a conductive trace, at least one of: a width of the conductive trace being 3D-printed, and a thickness of the conductive trace being 3D-printed; wherein the on-the-fly trace width/thickness modifier is to perform modification of the width and/or thickness of the conductive trace while maintaining a fixed current-carrying capacity of said conductive trace.

In some embodiments, the device comprises: a rigidity/flexibility modifier to 3D-print a PCB having a gradually-changing level of rigidity.

In some embodiments, the device comprises: a rigidity/flexibility modifier to 3D-print a PCB having an abruptly-changing level of rigidity.

In some embodiments, the device comprises: a dielectric material thickness modifier to 3D-print, between a first 3D-printed conductive layer and a second, neighboring, non-parallel, 3D-printed conductive layer, a dielectric material having varying thickness.

In some embodiments, the device comprises: a non-parallel layer 3D-printing module to 3D-print a conductive material to create a three-dimensional structure of a first layer of a PCB and a second, non-parallel, layer of the PCB.

In some embodiments, the device comprises: a non-parallel layer 3D-printing module to 3D-print: (A) a first 3D-printed conductive layer, and (B) a second, neighboring, non-parallel, 3D-printed conductive layer. In some embodiments, the device comprises: a compensating module to compensate for non-parallelism of the first and second 3D-printed conductive layers by modifying a thickness of a 3D-printed dielectric material between said first and second 3D-printed conductive layers. In some embodiments, the compensating module is to modify a width of a 3D-printed trace in order to maintain a constant impedance of the 3D-printed conductive trace in regions having different thickness of the 3D-printed dielectric material.

In some embodiments, the device comprises: a liquid-based cooling tube 3D-printing module, to 3D-print a sealed liquid-based cooling tube from a thermally-conductive 3D-printing material.

In some embodiments, the first 3D-printing head is to discharge conductive ink; or to discharge ink or conductive ink impregnated with metallic nano-particles or with conductive nano-particles.

In some embodiments, the device comprises: a cooling module to discharge liquid nitrogen for curing of 3D-printed materials.

In some embodiments, the device comprises: a barometric-pressure related curing module, to selectively modify a barometric pressure of a dispensing chamber of said device to cause curing of at least one of: the conductive 3D-printing material, and the insulating 3D-printing material.

In some embodiments, the device comprises: an inter-layer transition placement module to enhance a distribution of inter-layer transitions to be 3D-printed, based on a target overall thickness of an intended 3D-printed PCB.

In some embodiments, the device comprises: an inter-layer transition placement module to determine that an inter-layer transition, that was planned to be fabricated at a first X-Y location, is to be 3D-printed at a second, different, X-Y location, based on a target overall thickness of an intended 3D-printed PCB.

In some embodiments, the device is to 3D-print a functional PCB in a lamination-free process.

In some embodiments, the device comprises: an Impedance-Controlled Via 3D-printing module to 3D-print an inter-layer via as an extension of a 3D-printed conductive trace.

In some embodiments, the device comprises: an Impedance-Controlled Via 3D-printing module to 3D-print an inter-layer via as an extension of a 3D-printed conductive trace; wherein the 3D-printed inter-layer via has a shielding identical to a shielding of said 3D-printed conductive trace.

In some embodiments, the device comprises: an Impedance-Controlled Via 3D-printing module (A) to determine that an inter-layer via is to be 3D-printed at a particular distance from a ground plan to maintain a pre-defined impedance value of a 3D-printed conductive trace; and (B) to 3D-print the inter-layer via at said particular distance from the ground plan.

In some embodiments, the device comprises: a Z-axis balancing module to adjust a 3D-printing process of a PCB being 3D-printed by maintaining a balance, relative to Z-axis, of said PCB being 3D-printed. In some embodiments, the balance is maintained by the Z-axis balancing module by performing at least one of: utilizing one or more weights, selectively placed at one or more regions of the PCB being 3D-printed; modifying a pre-planned order of execution of said 3D-printing process; modifying a selection of 3D-printing materials being used.

In some embodiments, the first and second 3D-printing heads are to 3D-print a functional optical waveguide.

In some embodiments, the device comprises: a verification module, integrated in said device, to verify that two or more points of a 3D-printed PCB, that are intended to be conductively connected, are indeed conductively connected.

The present invention may provide other and/or additional benefits or advantages.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIGS. 1A-1F are schematic block-diagram illustrations of a three-dimensional printer and its components and modules, in accordance with some demonstrative embodiments of the present invention;

FIG. 2 is a schematic illustration of a side-view of a prior art PCB having even stack-up of layers;

FIG. 3 is a schematic illustration of a side-view of a 3D-printed PCB having uneven stack-up of non-parallel layers, in accordance with some demonstrative embodiments of the present invention;

FIG. 4 is a schematic illustration of a cross-section of a 3D-printed PCB, demonstrating multiple 3D-printed vias or “Via Equivalent” structures, which may be 3D-printed in accordance with the present invention; and

FIGS. 5A-5C are schematic illustrations of conductive traces, demonstrating 3D-printing of “trace skipping” or “trace bridging”, in accordance with some demonstrative embodiments of the present invention.

### DETAILED DESCRIPTION OF THE PRESENT INVENTION

In the following detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

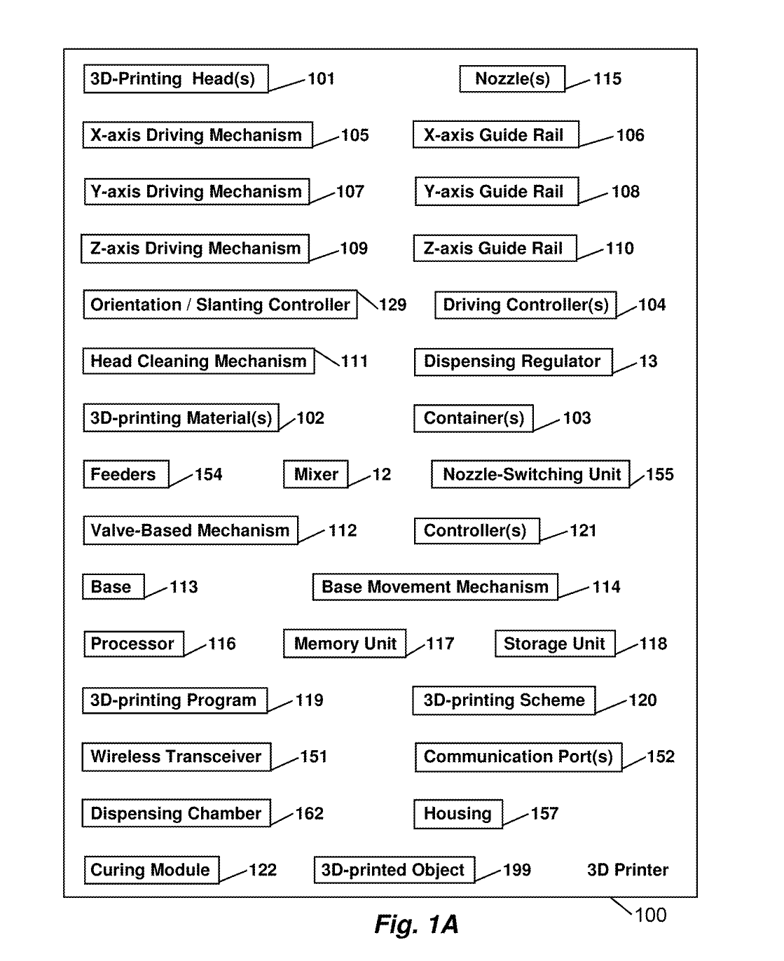

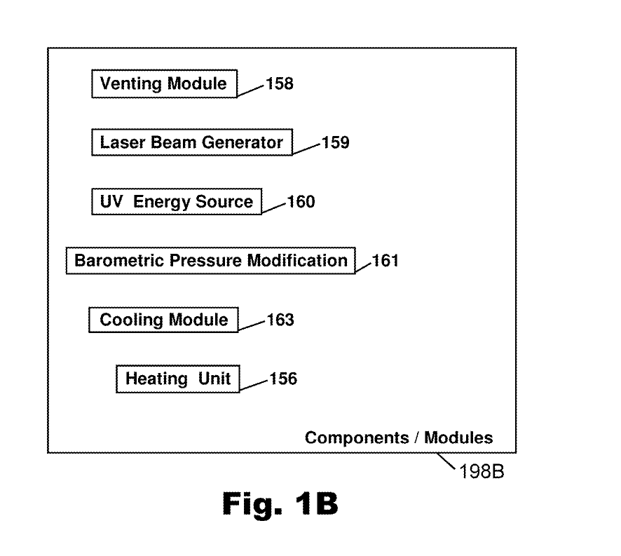

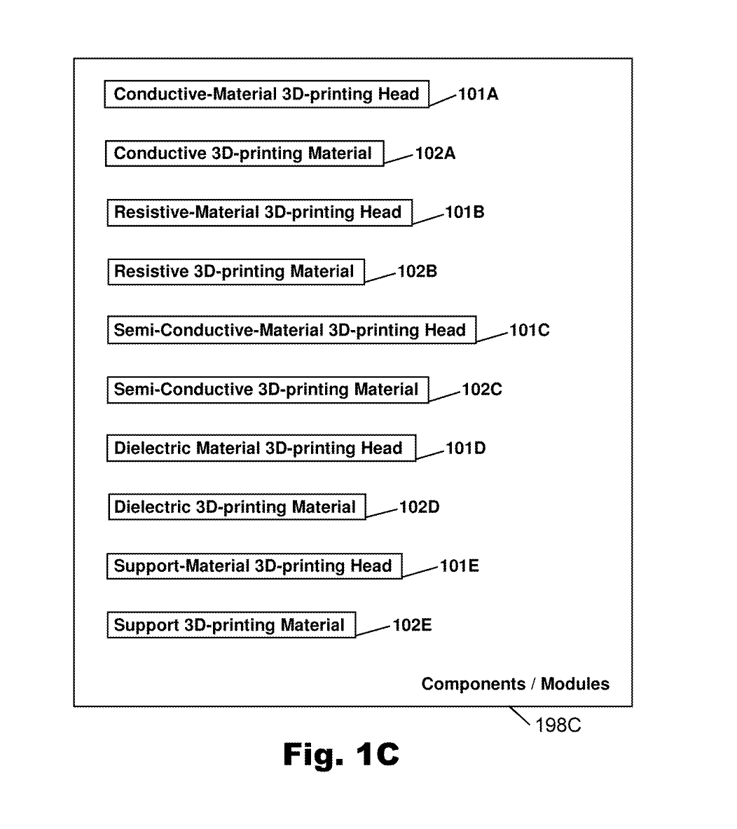

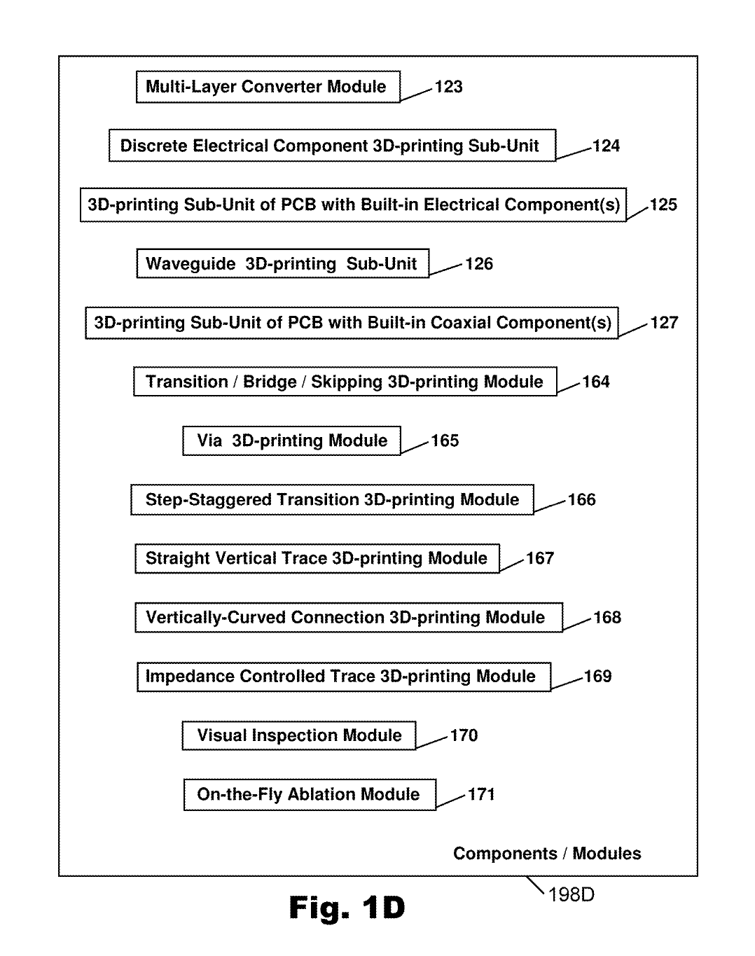

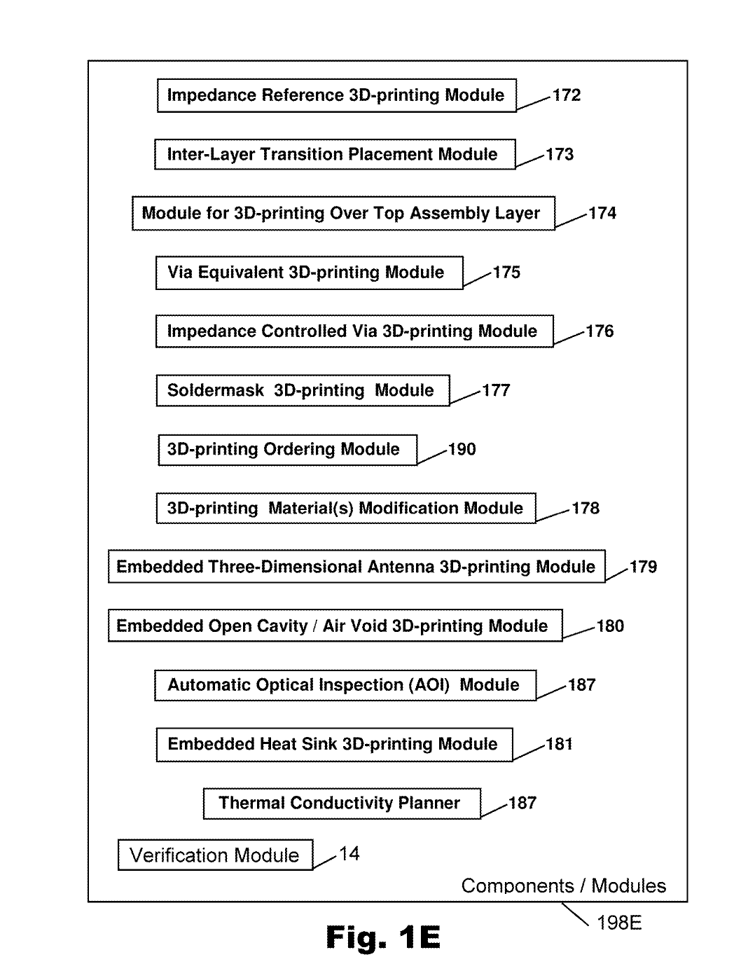

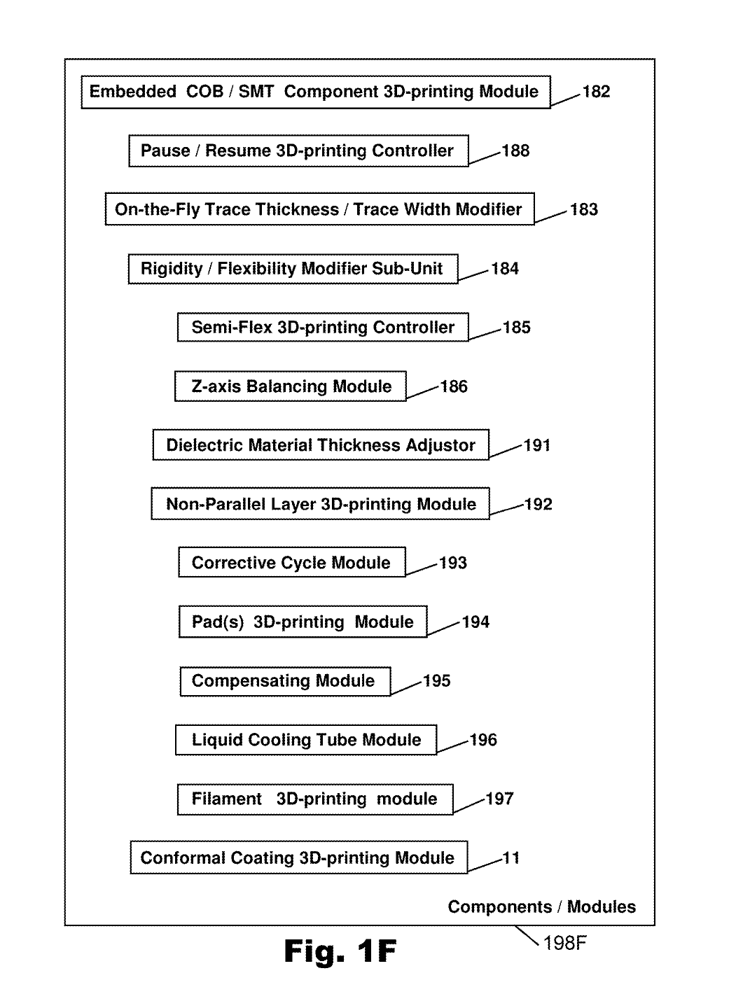

Reference is made to FIGS. 1A-1F, which are schematic block-diagram illustrations of a three-dimensional (3D or 3-D) printer 100 and its components and modules, in accordance with some demonstrative embodiments of the present invention. The 3D printer 100 may comprise some or all of the components and/or modules that are depicted in FIG. 1A; and/or one or some or all of additional components/modules 198B which are depicted in FIG. 1B; and/or one or some or all of additional components/modules 198C which are depicted in FIG. 1C; and/or one or some or all of additional components/modules 198D which are depicted in FIG. 1D; and/or one or some or all of additional components/modules 198E which are depicted in FIG. 1E; and/or one or some or all of additional components/modules 198F which are depicted in FIG. 1F.

The components and/or modules of 3D printer 100 may be implemented using hardware, using software, and/or using a combination of hardware and software. Some components or modules, that are shown as separate or discrete components or modules or elements or units, may be implemented as a unified or integrated component capable of performing multiple functions. Components and/or modules that appear in FIGS. 1A-1F may be co-located within a single housing or apparatus; or may be operably associated with each other; or may be able to communicate with each other using wires, cables, wireless links, wired links, communication links, communication bus, or the like.

3D printer 100 may comprise one or more 3D-printing head(s) 101. Each printing head 101 may be able to inject or discharge or output one or more 3D-printing material(s) 102, via one or more nozzles 115 (e.g., having different aperture size, or aperture diameter, or aperture radius, or aperture cross-section, or aperture shape, or throughput; e.g., different throughput measured by coverage in cm²-per-second or in cm³-per-second).

Printing material(s) 102 may be stored in one or more container(s) 103. The container(s) 103 may be an integral part of printing head(s) 101; or may be an add-on to (or extension of) printing head(s) 101; or may be external to the printing head(s) 101 (e.g., may be connected to the printing head(s) 101 via tubes or pipes).

Optionally, each printing head 101 may comprise (or may be associated with) a mixer 12; and/or, each container 103 (or a set or group or batch of containers 103) may comprise (or may be associated with) mixer 12. For example, mixer 12 may perform mixing of two or more 3D-printing materials, optionally from two different containers 103 (or from a single container 103 in which multiple 3D-printing materials may be stored), to mix and/or shake and/or blend and/or stir the 3D-printing materials prior to their dispensing or discharging. In some implementation, a 3D-printing material may need to be mixed with another material (e.g., an agent or catalyst) in order to be “activated” and to become ready for dispensing (and/or for rapid curing subsequent to dispensing).

For example, some 3D-printing materials may be pre-provided in a non-mixed state, since (optionally) mixing or partial mixing may affect curing or may cause curing or may hasten curing, or may cause or hasten solidification, or may shorten or decrease the shelf-life of the 3D-printing materials; or may have other effects which may be undesired as long as the 3D-printing materials are only stored and not discharged (whereas such effects may be desired, or may be non-adverse, once the materials are mixed and discharged shortly after the mixing). Accordingly mixer 12 may operate shortly prior to the actual dispensing or discharging of the 3D-printing material(s).

Each one of printing head(s) 101 may be able to move (e.g., back and forth) along an X-axis and/or along a Y-axis and/or along a Z-axis. The X-axis may be generally perpendicular to the Y-axis and to the Z-axis. The Y-axis may be generally perpendicular to the X-axis and to the Z-axis. In a demonstrative implementation, a demonstrative printing head 101 may be able to move along the X-axis by using an X-axis driving mechanism 105 and an X-axis guide rail 106. Similarly, printing head 101 may be able to move along the Y-axis by using a Y-axis driving mechanism 107 and a Y-axis guide rail 108. Similarly, printing head 101 may be able to move along the Z-axis by using a Z-axis driving mechanism 109 and a Z-axis guide rail 110.

Optionally, each printing head 101 may further be controlled by an orientation/slanting controller 129, which may set or modify the orientation or slanting of each printing head 101, or the direction towards which each printing head 101 is directed; for example, in order to allow printing head 101 to discharge printing material(s) 102 in a non-vertical direction, or in horizontal direction, or in a slanted or diagonal direction (e.g., in order to penetrate or to reach hard-to-reach places, or in order to achieve a particular 3D-printed structure which may require side-printing or slanted 3D-printing).

One or more driving controller(s) 104 may control, start, stop, pause, set, or otherwise modify the movement (and/or the slanting or orientation) of the printing head(s) 101, or may otherwise set or modify characteristic(s) of such movement (and/or slanting or orientation) of printing head(s) 101, for example, acceleration, deceleration, velocity of movement, timing of movement, or the like. Driving controller(s) 104 may cause multiple printing heads 101 to move simultaneously or concurrently, or to move in series or in sequence.

3D printer 100 may further comprise a base 113, which may be a surface or region or area onto which (or into which) the printing material(s) 102 may be injected or discharged, and onto which (or into which) a desired 3D-printed object 199 is intended to be injected and thus created. In some embodiments, base 113 may be generally fixed and static, and may not move or tilt. In other embodiments, base 113 may be associated with a base movement mechanism 114, able to move the base 113 (e.g., along the X-axis, and/or along the Y-axis, and/or along the Z-axis), or able to modify the orientation or position or slanting or tilting or location of base 113 (e.g., able to rotate or spin or tilt or slant the base 113). Such movement of base 113 may be utilized in order to facilitate and/or to hasten the 3D-printing process, or in order to partially replace movement of one or more printing head(s) 101, or in order to facilitate accurate 3D-printing of printing material(s) in particular hard-to-reach places.

In some embodiments, each printing head 101 may inject or discharge (or may output) exactly one type of material; for example, in order to avoid contamination or impurities which may occur if a single printing head 101 is used to firstly inject or discharge a first 3D-printing material (which may leave residue) and subsequently to inject or discharge a second, different, 3D-printing material.

In other embodiments, each 3D-printing head 101 may be able to inject or discharge (or may output) a first 3D-printing material 102, and subsequently may be able to inject or discharge (or may output) a second, different, 3D-printing material 102; for example, if contamination or impurity does not interfere with the structure or the function of the 3D-printed object 199; or if a 3D-printing head cleaning mechanism 111 is utilized between successive discharges that utilize different 3D-printing materials 102 (e.g., in order to remove from 3D-printing head 101 residue(s) of previously-injected material(s) prior to 3D-printing a new 3D-printing material via that 3D-printing head 101).

In some embodiments, a valve-based mechanism 112 may be used to control or regulate which 3D-printing material(s) 102 are injected or discharged via which printing head(s) 101; or in order to allow or disallow access of a particular 3D-printing head 101 to a particular 3D-printing material 102 (or vice versa). Optionally, a dispensing regulator 13 or other suitable component (e.g., a pump, a suction unit, a compressor, a pushing unit, a pulling unit) may operate to push the 3D-printing material 102 or to inject it or dispense it through the relevant 3D-printing head(s) 101; and such dispensing regulator 13 may control the amount of 3D-printing material(s) 102 being deposited or dispensed or discharged, the timing of the dispensing, the force of the dispensing, or the like.

3D printer 100 may further comprise a processor 116, a memory unit 117, and a storage unit 118. For example, storage unit 118 may store a 3D-printing program 119, which may be executed by processor 116 (e.g., utilizing memory unit 117 for interim calculations or for short-term storage of data).

The 3D-printing program 119 may comprise, or may receive as input (e.g., from an external device, or from a remote device, or from a “cloud computing” server or device, or from other local or remote source, via one or more wired links and/or wireless links) a 3D-printing scheme 120 which may be a computer-aided design (CAD) file describing the properties of the desired object. Optionally, 3D-printing scheme 120 may be wirelessly received by 3D-printer 100 via a wireless communication link by utilizing a built-in or embedded wireless communication transceiver 151; or may be received over a wired link through one or more communication port(s) 152 of 3D-printer 100, for example, a USB port, a Firewire port, a Thunderbolt port, or the like.

For example, 3D-printing scheme 120 may be represented as a CAD file, as an STL file (Stereo-Lithography file, or Standard Tessellation Language file), as a PLY file (Polygon File Format, or Stanford Triangle Format), as a VRML file (Virtual Reality Modeling Language file, or Virtual Reality Markup Language file, an X3D file, a CAD or AutoCAD file (e.g., DXF file, Drawing Interchange Format, Drawing Exchange Format), a DWG file, a Gerber file (e.g., describing PCB elements), an EMN file (e.g., utilized by Pro/ENGINEER software such as Wildfire, or other PTC software), or the like.

Processor 116 may execute the 3D-printing program 119 to process and/or render the 3D-printing scheme 120. Based on such processing or rendering (or, as a part of such processing or rendering), processor 116 may selectively activate and/or deactivate one or more components of 3D-printer 100 (e.g., the printing head(s) 101, or selectively any one of them), or may otherwise instruct such component(s) of 3D-printer 100 to modify their operational properties (e.g., to start operation, to stop or pause operation, to move, to remain non-moving, to inject or discharge or deposit printing material(s), or the like).

Optionally, one or more controllers 121 or other components may be used as intermediary sub-units, in order to facilitate the acting upon the operational instructions generated by processor 116; such that, for example, processor 116 may instruct the relevant controller(s) 121 which action is required, and the relevant controller(s) 121 may accordingly control the corresponding component(s) of 3D-printer 100 (e.g., one or more of the 3D-printing head(s) 101, and/or the base 113).

Based on the instructions from processor 116, the 3D-printing head(s) 101 may selectively move (and optionally, tilt), and may selectively inject or discharge or deposit one or more 3D-printing material(s) 102 towards pre-defined direction(s) or target(s), e.g., towards particular locations or regions on base 113 or relative thereto.

The 3D-printing material(s) 102 may be or may comprise, for example, one or more liquid(s), one or more solid material(s), particulate material(s), granulated material(s), polymer(s), powder(s), powdered material(s), flakes, flaked material(s), or any suitable combination thereof.

The deposited or discharged 3D-printing material(s) 102 may harden or cure or solidify, immediately or shortly after their discharge, or subsequently; for example, due to a natural process (e.g., the material hardening over time), and/or due to one or more curing or hardening processes initiated by 3D printer 100. For example, a curing module 122 or other suitable module(s) may provide heating and/or cooling to the discharged 3D-printing material(s) 102 and/or to the 3D-printed object 199 being printed, or may otherwise facilitate or hasten the curing or hardening or solidifying thereof (e.g., by illuminating an ultraviolet light at a particular wave-length).

In some embodiments, optionally, 3D-printer 100 may discharge a first 3D-printing material 102 which (by itself) does not necessarily harden immediately, or does not necessarily solidify immediately; and may then discharge a second 3D-printing material 102 which (by itself) does not necessarily harden immediately, or does not necessarily solidify immediately; such that the contact or touching between these first and second 3D-printing materials 102, may cause both of them to harden or solidify (e.g., due to bonding or binding, or chemical reaction or chemical bonding or chemical binding or fusion).

In some embodiments, each 3D-printing material 102 being used may comprise particles (or “3D dots”) which may have a diameter of about, for example, 100 micrometer, or 80 micrometer, or 60 micrometer, or 50 micrometer, or 40 micrometer, or 30 micrometer, or 20 micrometer, or 16 micrometer, or 15 micrometer, or 10 micrometer, or other suitable size.

In some embodiments, the 3D-printing resolution and/or accuracy of 3D-printer 100 may be about, for example, 100 micrometer, or 80 micrometer, or 60 micrometer, or 50 micrometer, or 40 micrometer, or 30 micrometer, or 20 micrometer, or 16 micrometer, or 15 micrometer, or 10 micrometer, or other suitable size.

In some embodiments, 3D printer 100 may be able to 3D-print and produce layer thickness of about, for example, 100 micrometer, or 80 micrometer, or 60 micrometer, or 50 micrometer, or 40 micrometer, or 30 micrometer, or 20 micrometer, or 16 micrometer, or 15 micrometer, or 10 micrometer, or other suitable size.

In some embodiments, the 3D printer 100 may be able to 3D-print (e.g., to deposit the printing material(s) 102) at a layer thickness of about, for example, 100 micrometer, or 80 micrometer, or 60 micrometer, or 50 micrometer, or 40 micrometer, or 30 micrometer, or 20 micrometer, or 16 micrometer, or 15 micrometer, or 10 micrometer, or other suitable size.

In some embodiments, 3D printer 100 may be able to 3D-print (e.g., to deposit the printing material(s) 102) at an X-Y resolution (or at a Z-axis resolution; or at an X-axis resolution; or at a Y-axis resolution) of about, for example, 300 dots-per-inch (DPI), or 400 DPI, or 600 DPI, or 1,200 DPI, or 2,400 DPI, or 4,800 DPI, or 9,600 DPI, or other suitable resolution(s).

The term “circuit” as used herein may include, for example, an electric circuit, an Integrated Circuit (IC), a Printed Circuit Board (PCB), a single-layer circuit, a multiple-layer or multi-layer circuit, a multi-layer or multiple-layer PCB, a multi-plane or multiple-plane circuit or PCB, or the like. Such “circuit” may have a particular function, for example, an amplifier, an oscillator, a radio receiver, a radio transmitter, or the like.

The term “electrical component” as used herein may include a circuit and/or any suitable component which may be a part of a circuit; or any discrete device which may be used to affect (directly or indirectly) electrons or their associated fields; for example, an active component, a passive component, a diode, a varactor, a transistor, a connector, a pad or conductive pad or “land”, a Field-Effect Transistor (FET), a resistor, a rheostat, a potentiometer, a capacitor, an opto-electronic component or device, a digital IC, an analog IC, a sensor (e.g., a Hall effect sensor, a current sensor), a Light Emitting Diode (LED), a battery, a power cell, a photo-voltaic device, a magnetic or inductive device, an inductor or coil, a transformer, an RC circuit, an LC circuit, an antenna, a Van de Graaff generator, a device utilizing piezoelectric effect and/or piezoelectric pressure, a waveguide, an electromagnetic waveguide, an optical waveguide, an acoustic waveguide, a wire, a conductive strip or channel or line or region, an isolating (or non-conductive) strip or channel or line or region, a semi-conducting strip or channel or line or region, a coaxial component or cable or mesh, or the like.

It is noted that the term “electrical component” may exclude objects or items or articles that a conventional electric engineer may not typically classify as a component that is used in conventional electric circuits, or objects that do not have a miniature size or a sufficiently-small form-factor to be included in electric circuits or electronic devices. For example, a ceramic vase capable of holding flowers, or a ceramic ashtray capable of holding cigarettes, may not be regarded as a “resistor” for the purposes of the present invention, even though such device may be formed (or even, may be 3D-printed) of ceramic which may be electrically-insulating, since a vase or ashtray are not typically regarded as an electrical component used in assembling or producing electronic circuits or devices, and/or since a vase or ashtray do not have a sufficiently-small form factor to be suitable for inclusion in such electric circuits or electronic devices.

In accordance with the present invention, 3D printer 100 may 3D-print a functional circuit or PCB, or may 3D-print one or more functional electrical components which may be stand-alone (e.g., may be then assembled into or onto other circuits) or may be embedded within a 3D-printed circuit or PCB (e.g., by optionally using a single or unified 3D-printing process to 3D-print in a single 3D-printing session both the PCB and an electric component embedded therein as an integrated component).

For example, 3D-printing head(s) 101 may selectively move and/or rotate and/or change their position or location or orientation, and may selectively discharge or inject (e.g., at particular spatial locations, and in particular timing) one or more 3D-printing material(s) 102. For example, a conductive-material 3D-printing head 101A may discharge a conductive 3D-printing material 102A; a resistive-material printing head 101B may discharge a resistive (or isolating, or insulating) 3D-printing material 102B; a semi-conductive-material 3D-printing head 101C may discharge a semi-conductive 3D-printing material 102C; a dielectric material 3D-printing head 101D may discharge a dielectric 3D-printing material 102D; and/or a support-material 3D-printing head 101E may optionally discharge a support 3D-printing material 102E (e.g., able to provide temporary or long-term structural support to other 3D-printed components or structures). Optionally, one or more 3D-printing head(s) 101 may be dedicated to 3D-print a particular material or a particular combination of materials; for example, a ceramic material 3D-printing head 101F may discharge one or more ceramic 3D-printing material(s) 102F (e.g., may be utilized for 3D-printing of a capacitor or other electrical components, or electronic components). The 3D-printing head(s) 101 may operate in series or in sequence, or in parallel, or in partially-overlapping or fully-overlapping time periods; or in accordance with a particular timing scheme, ordering scheme, pause-and-resume scheme, turn-taking scheme, or the like.

In some embodiments, the terms “insulating” or “insolating” or “isolating” may include, for example, resistive, highly-resistive, electrically insulating, electrically isolating, non-conductive, having high electrical resistivity, having low or no electrical conductivity, opposing the flow of electric current.

In some embodiments, the top and bottom conductive layers are where the pads for assembly may be 3D-printed. Assembly of components may be done on the top and bottom layers.

Optionally, 3D printer 100 may discharge printing material(s) 102 which may solidify or may cure immediately (or substantially immediately) upon their discharge, or upon their contact with room-temperature air, or upon their contact with air having a particular temperature (or range of temperatures); or upon being exposed to a particular barometric pressure (e.g., which the 3D-printer may be able to selectively set or modify).

In some embodiments, 3D printer 100 may 3D-print a circuit or PCB by using a layer-by-layer process or additive process; for example, printing a first layer, optionally waiting for the first layer to cure or solidify; then 3D-printing one or more Vias (or 3D-printed Via Equivalents as described herein) or inter-layer components; then 3D-printing a second layer on top of the first layer; optionally waiting for the second layer to cure or solidify, and so forth, layer by layer.

In other embodiments, 3D printer 100 may 3D-print a multi-layer circuit or PCB as a mono-block 3D-printed object, in a non-layer-by-layer technique, or in a process that obviates the need to 3D-print layer-by-layer (and/or to wait between 3D-printings of layers). For example, 3D printer 100 may utilize a multi-layer converter module 123 which may take a circuit design reflecting multiple layers, and may convert or transform such circuit design into a three-dimensional structural design that is free of layer-by-layer information or constraints, or a three-dimensional structural design that need not be printed as a layer-by-layer structure by rather may be printed as a unified three-dimensional object; such that, for example, portions of Layers 1 and 2 and 3 may be 3D-printed, prior to the complete 3D-printing of Layer 1.

In some embodiments, 3D printer 100 may include, or may be associated with, or may be implemented as, a discrete electrical component 3D-printing sub-unit 124 which may be able to 3D-print and produce a stand-alone or freestanding electrical component, which may be fully functional and operational. This may obviate the need, for a manufacturer or maker of circuits, to maintain or to purchase a large stock or inventory of a variety of electrical components having a variety of properties; and instead, may allow printing-on-demand of discrete electrical component(s) (e.g., resistor, capacitor, or the like) having particular properties, electrical properties, mechanical properties, dimensions, or the like.

In some embodiments, 3D printer 100 may include, or may be associated with, or may be implemented as, a 3D-printing sub-unit 125 of PCB with built-in electrical component(s), and may be able to 3D-print or produce a PCB having integrated therein (or having embedded therein) one or more particular electrical components, which may be built-in within the PCB and may be 3D-printed (namely, produced) simultaneously with the PCB itself, in a single 3D-printing process or iteration, or as a unified 3D-printed object that comprises both the PCB and the electrical component co-printed therewith; rather than being separately produced and then being connected or soldered or assembled or attached to the PCB.

For example, 3D-printing sub-unit 125 of PCB with built-in electrical component(s) may be able to 3D-print or produce, directly, a three-dimensional structure which, when connected to electric current, may function as a fully-functional PCB having embedded therein one or more particular (and functional) electrical components (e.g., a resistor, a capacitor, a waveguide, a coaxial cable or element or mesh or component). This may obviate the need, for example, to 3D-print or produce a PCB, and to separately 3D-print or produce or purchase discrete electrical component(s), and then to solder or otherwise assemble or connect the discrete electrical components to the 3D-printed PCB. In some embodiments, passive electrical components (e.g., capacitors, resistors) may be 3D-printed on-the-fly at virtually any point or location along the X-axis, Y-axis and/or Z-axis; between layers, on top of a layer, underneath a layer, embedded within a layer, next to a layer, through multiple layers, or the like. Since 3D printer 100 may utilize multiple 3D-printing materials 102 for 3D-printing a PCB or for 3D-printing a single layer, a wider range of electrical properties may be reach with regard to such 3D-printed electrical components.

In some embodiments, 3D printer 100 may include, or may be associated with, or may be implemented as, a waveguide 3D-printing sub-unit 126 able to produce a 3D-printed PCB with built-in or integrated 3D-printed and fully-functional waveguide(s) (e.g., electromagnetic waveguide, optical waveguide, acoustic waveguide), and may be able to 3D-print or produce a PCB having integrated therein (or having embedded therein) one or more such 3D-printed waveguide(s), which may be built-in within the PCB and may be 3D-printed (namely, produced) simultaneously with the PCB itself; rather than being separately produced and then being connected or soldered or attached to the PCB.

For example, waveguide 3D-printing sub-unit 126 may be able to 3D-print or produce, directly, a three-dimensional structure which, when connected to electric current, may function as a fully-functional PCB having embedded therein one or more particular (and functional) waveguide(s). This may obviate the need, for example, to 3D-print or produce a PCB, and to separately 3D-print or produce or purchase waveguide(s), and then to solder or bond or glue or assemble or otherwise connect the discrete waveguide(s) to the PCB. Furthermore, this may allow a smooth transition or a smoother transition, or a less lossy transition, or a non-lossy transition, or a reduce-loss transition, from other portions (or components) of the PCB to the built-in waveguide, and/or from the waveguide to other portions (or components) of the PCB.

In some embodiments, an embedded waveguide may be 3D-printed on-the-fly in the circuit board or PCB being 3D-printed, and while such PCB is being 3D-printed. For example, a waveguide may be a conductive rectangular structure (e.g., a box, a cuboid) that defines boundary conditions for the propagation of electromagnetic waves. The waveguide may be 3D-printed on-the-fly, into and/or onto the PCB being 3D-printed; and such embedded 3D-printing may significantly reduce the propagation loss of signals (e.g., at signal entry into the waveguide; within the waveguide; and/or at signal exit from the waveguide).

In some embodiments, the waveguide may be 3D-printed with the conductive material, for example, onto a rectangular shape or structure or border or foundation which may be pre-made (e.g., by 3D-printing of isolating material). A cap of the waveguide may be 3D-printed on a support material that, after completion, may be washed away (e.g., if the support material is water soluble) or blown away (e.g., with an air push) or otherwise removed (e.g., by a delicate mechanical pulling-away or pushing-away of such support material). Once the cap is completed, the waveguide itself may be 3D-printed by using only conductive materials.

Similarly, an optical waveguide may be 3D-printed, as a stand-alone component, or as an integrated or built-in component as integral part of a 3D-printed PCB (e.g., in the same 3D-printing session). The 3D-printing material(s) may be selected, for 3D-printing the optical channel of signal propagation, to control the speed and the bandwidth of the signal propagating through the optical channel. 3D-printed coating of the optical channel may have reflecting properties, to allow the wave to propagate towards a specific direction or destination. The 3D-printing additive process may allow incremental formation of such optical channel, with fixed or varying materials, having one or more suitable optical fraction coefficient(s), thereby creating a 3D-printed optical waveguide. The implementation may be done with rigid material(s) and/or flex material(s). The 3D-printed waveguide or optical waveguide may have horizontal orientation (e.g., connecting components or source/destination on the same plane), or vertical orientation (e.g., connecting components or source/destination on different planes along the Z-axis), or slanted or diagonal orientation (e.g., connecting components or source/destination having a relative Z-axis offset, as well as a relative X-Y offset).

In some embodiments, 3D printer 100 may include, or may be associated with, or may be implemented as, a 3D-printing sub-unit 127 of PCB with built-in coaxial component(s), and may be able to 3D-print or produce a PCB having integrated therein (or having embedded therein) one or more coaxial component(s) (e.g., a coaxial cable, a coaxial cable mesh, a coaxial mesh, a coaxial network), which may be built-in within the PCB and may be 3D-printed (namely, produced) simultaneously with the PCB itself; rather than being separately produced and then being connected or soldered or assembled or attached to the PCB.

The terms “coax” or “coaxial” as used herein may include, for example, a cable or mesh or element or other structure comprising (a) an inner conductor, surrounded by (b) a tubular or generally-tubular insulating layer, surrounded by (c) a tubular or generally-tubular conducting shield; optionally surrounded by (d) an insulating outer jacket or sheath or sleeve.

For example, 3D-printing sub-unit 127 of PCB with built-in coaxial component(s) may be able to 3D-print or produce, directly, a three-dimensional structure which, when connected to electric current, may function as a fully-functional PCB having embedded therein one or more particular (and functional) coaxial component(s) or elements, e.g., a coaxial cable, a coaxial mesh or net or layer, a coaxial region or wire, or the like. For example, a first half of C-shaped section of an outer tube may be 3D-printed; then an inner layer or tube may be 3D-printed; and then the other half of C-shaped section of the outer tube may be 3D-printed; and this may be repeated for two or more such tubular components, alternating between 3D-printing of resistive material and conductive material.

This may obviate the need, for example, to 3D-print or produce a PCB, and to separately 3D-print or produce or purchase coaxial component(s), and then to solder or bond or assemble or glue or otherwise connect the discrete coaxial component(s) to the PCB. Furthermore, this may allow a smooth transition or a smoother transition, or a less lossy transition, or a non-lossy transition, or a reduced-loss transition, from other portions (or components) of the PCB to the built-in coaxial component, and/or from the coaxial component to other portions (or components) of the PCB.

Some embodiments may thus allow on-the-fly 3D-printing of embedded coaxial cable in the circuit board or PCB. For example, for isolating purposes, a silver epoxy mesh or other highly-conductive material may be 3D-printed around a trace that needs to be insulated. The contraction of the 3D-printed mesh may be done, for example, once a support half tube is 3D-printed from the isolating material; then silver (or other suitable conductive material) may be 3D-printed onto the support tube in the required pattern; and a second (top) section of the mesh may be 3D-printed on top of the insulator material, covering the traces (the barrel).

For example, the system may 3D-print a circular (or cylindrical) mesh around a conductor, in order to provide the insulation and form a coaxial cable. Optionally, the 3D-printing process may comprise multiple sessions or parts, in order to support the coaxial structure or to achieve a barrel or cylindrical structure. For example, a first half of the tube or barrel may be 3D-printed; and then, the insulation material may be 3D-printed on top of the conductor in a round shape, and then 3D-print on top of it the mesh which provides the insulation or the coaxial properties. Optionally, a 3D-printed coax (or coaxial cable or component) may further be utilized as a dedicated ground reference layer to one or more specific 3D-printed trace(s); and this may release the human professional who designs a PCB from constraints associated with impedance calculation (which, in turn, may impact the PCB stack-up).

Optionally, rapidly curing materials may be used, in order to form insulation layers without mechanical support; for example, if air is the desired dielectric material between the conductors (traces) and the shielding layer. Other suitable dielectric material(s) may be used or 3D-printed; for example, an electrical insulator that can be polarized by an applied electric field (e.g., dielectric polarization).

The 3D printer 100 may perform 3D-printing of a PCB by using an additive process of selectively and accurately building-up layers or regions or portions of conductive materials and/or insulating materials according, to predefined Computer-Aided Design (CAD) pattern or graphics or layout or scheme. The resulting PCB may allow to interconnect electronic components utilizing Surface-Mount Technology (SMT) and through hole assembly process (e.g., in accordance with the Restriction of Hazardous Substances (RoHS) Directive 2002/95/EC, also known as “Directive on the restriction of the use of certain hazardous substances in electrical and electronic equipment”, adopted in February 2003 by the European Union; as well as RoHS-compliant and/or non-RoHS-compliant processes).

The 3D printer 100 may be able to 3D-print multiple insulating materials with different electrical properties, and conductive materials that may be used as traces to interconnect electronic components.

For example, when 3D-printing a single-layer PCB, the 3D-printer 100 may begin to 3D-print an insulator layer, which may be applied to a premade insulator to save processing time; and finish with the conductor printing on top of the insulator layer.

In 3D-printing of a multiple-layer PCB, the process may start with 3D-printing an insulation layer sheet as a baseline; and 3D-printing which builds-up from there and upward the conductive layer(s) or regions, optionally using 3D-printing of insulation material(s) to allow crossing or bridging or skipping between conductive traces. The top and bottom layers (conductive layers) may be 3D-printed as generally planar, to facilitate SMT pick-and-place assembly, for example, within 3 or 5 or 10 percent of the thickness of the finished 3D-printed PCB.

The 3D-printing process of the PCB may start with 3D-printing of the bottom layer (layer 1), upwardly, all the way up to the top layer; and then, optionally, flipping or turning the PCB upside-down in order to 3D-print the bottom conductive layer (which, after such flipping, may be on the top side and nearest to the printing head(s) 101 and ready to receive 3D-printing material(s) 102 discharged thereto).

Interconnection between traces that run on different layers or planes, may be done by 3D-printing of Vias (or 3D-printed Via Equivalents); or by skipping traces during the build-up process.

The Vias in a 3D-printed PCB need not be drilled and/or plated; but rather, such Vias may be 3D-printed, for example, by 3D-printing the insulating material around the location that is planned for such a “via”, and then 3D-printing conductive material into a “barrel” created by the isolating filament. The terms “via” or “via equivalent” as used herein may include, for example, a suitable 3D-printed structure and/or element which may correspond to a conventional (e.g., non-3D-printed) via or micro-via, or which may correspond to a drilled via. The terms “via” or “via equivalent” as used herein may optionally include, for example, a 3D-printed conductive trace which flows from a first layer or plane or region to a second (and/or third, and so forth) layer or plane or region of a 3D-printed PCB; or other suitable inter-layer transition or inter-plane transition or inter-region transition in a 3D-printed PCB.

An alternate method to avoid crossing of traces, when 3D-printing a PCB, is to perform 3D-printed skipping or bridging. Skipping may not require a via, and may be implemented by 3D-printing a localized insolating filament (“bridge”) on top of a first trace at the desired crossing point, and then 3D-printing a second trace on top of such “bridge” at the crossing point. Once passing the crossing point, the crossing trace(s) may be 3D-printed on the same plane or surface, thereby contributing to maintaining the entire 3D-printed PCB thin.

The conductive material for 3D-printing used may comprise, or may optionally be mixed with: gold, silver, silver paste, graphite, graphene (a thin crystalline allotrope of carbon; or a one atom thick layer of graphite), a mixture or paste of silver with graphite or graphene; or solder paste on the top and bottom layers, to avoid the need for surface finish and/or to provide a solid adhesion at the soldering stage.

The 3D-printing head(s) 101 may selectively sputter or deposit or discharge or shoot one or more 3D-printing material(s) 102. Optionally, base 113 or other table or suitable support structure or base unit may be used, and may be located inside a closed or encapsulated dispensing chamber 162. Optionally, base 113 and/or printing head(s) 101 may be controlled by the embedded or integrated or external processor 116 (or controller, or computer, or computing device. Optionally, 3D printer 100 may be connected to or associated with an external computing device, and in such case 3D printer 100 may comprise one or more embedded controllers 121 to translate the commands or data received from such external computer into internal instructions that 3D printer 100 performs.

The 3D printer 100 may comprise one or more feeders 154 or other feeding units, able to store and/or provide solid material(s) that may be melted by printing head(s) 101, or able to provide 3D-printing material(s) in liquid form (e.g., at a pre-defined viscosity level, or at varying viscosity levels to achieve particular implementation goals) or as powder or granules or flakes or particulate matter. Alternatively, feeders 154 may comprise 3D-printing material(s) 102 stored in suitable containers (e.g., one-time containers, single-use containers, multiple-use containers, refillable containers, replaceable containers), for example, in case the 3D-printing material(s) 102 are in liquid form or paste form, or other suitable form (e.g., particulate form) which may be suitable for storage in such containers.

Base 113 may be controlled (e.g., moved, tilted, slanted, oriented) in either one axis (for example, the Z axis), or in two axes (for example, Z and X axes; or Z and Y axes), or in three axes (namely, X and Y and Z axes). The 3D-printing head(s) 101 may be static and non-moving, for example, if base 113 may be able to move along all three axes; or, the 3D-printing head(s) 101 may be able to move in two axes (for example, X and Y axes) or in all three axes (namely, X and Y and Z axes).

Insulating materials that may be used in accordance with the present invention may comprise, for example, fiberglass reinforced materials; FR-4 or FR4 or other suitable composite material composed of woven fiberglass cloth with an epoxy resin binder that is flame resistant (e.g., self-extinguishing); glass-reinforced epoxy laminate materials; plastics; high-temperature plastics; ceramic (e.g., an inorganic non-metallic sold prepared by heat and subsequent cooling); Polytetrafluoroethylene (PTFE), Teflon material, filled-PTFE, Polyethylene (or polythene, or polyethene, or poly(methylene), or PE); hydrocarbon ceramic; or the like.

The 3D printer 100 may utilize conductive 3D-printing material(s) 102, for example, conductive ink, or epoxy, or resin, which may optionally be impregnated or mixed with metals (e.g., silver, gold, copper, and/or other suitable metal(s) or combinations thereof) or with one or more other particular materials, such as, silver particles, nickel, graphite, graphene, highly-conductive metallic particles, highly-conductive metallic micro-particles, highly-conductive metallic nano-particles). The resistivity of the conductive layers may be defined based on the requirement of the end-use of the PCB, for example, to achieve desired properties with regard to current consumption, loss and speed of propagation.

The use of both conductive materials and insulating materials may be determined based on the requirements of the end-user of the PCB; for example, multiple materials with different dielectric properties may be mixed and then discharged (namely, 3D-printed), in order to achieve the desired or optimal performance of the PCB.

In a demonstrative implementation, a computer may transmit commends to 3D printer 100 based on a CAD drawing or digital representation of the desired PCB or circuit (e.g., a single-layer circuit, or a multi-layer circuit); and printing head(s) 101 may move along the X-axis and/or the Y-axis, while base 113 may move along the Z-axis (e.g., downwardly and/or upwardly) once every layer is printed or while each layer is printed. In other implementations, base 113 may move along all three axes, such that generally-static 3D-printing head(s) 101 may be used; or, while one or more 3D-printing head(s) 101 are moving too.

The 3D-printing head(s) 101 may discharge or sputter or apply one or more 3D-printing material(s) 102 (e.g., mixed together, or in sequence, or in parallel). In some implementations, 3D printer 100 may comprise multiple 3D-printing heads 101 able to discharge multiple, different, 3D-printing materials 102 (for example, each such 3D-printing material 102 having a different melting temperature or drying temperature or curing temperature).

Each 3D-printing head 101 may comprise one or more nozzle(s) 115, which may be automatically and/or dynamically changed or switched by an on-the-fly nozzle-switching unit 155; such that, for example, a first nozzle 115 able to 3D-print a particular printing material at a particular speed or rate or force or diameter, may be exchanged or replaced on-the-fly with another nozzle 115 having other 3D-printing properties (e.g., a nozzle for 3D-printing a 6-mil trace; a nozzle for 3D-printing a 4-mil trace; or the like). For example, different PCBs may require different thickness of insulation materials and/or conductive materials, as well as different resolution of three-dimensional printing. The ability of printer 100 to automatically adjust or interchange or switch or rotate nozzles 115 on-the-fly and/or during a 3D-printing session, may increase the speed or the efficiency (or may reduce the time) at which a PCB may be 3D-printed, and may increase the robustness of the 3D-printing solution provided by 3D printer 100.

In some embodiments, a liquid cooling tube 3D-printing module 196 may be used in order to 3D-print a liquid cooling tube (or sealed channel, or chamber, or pipe, or other suitable container), which may be 3D-printed from thermally-conductive material(s) that may be electrically-conductive or electrically-resistive; and such sealed tube may comprise water or other liquid(s) (which may be injected thereto, or may be 3D-printed thereto) and may contribute to cooling of the 3D-printed PCB or to nearby components or regions.

The curing module 122 may cure the 3D-printed article (e.g., the PCB, the electric component, or the like), or particular portions or regions or elements thereof. Curing may be performed at one or more stages of the 3D-printing process, based on the printing material(s) 101 used for each circuit or PCB, their thickness, their properties, and/or the number of conductive layers that are used. The factors that may affect the curing of a 3D-printed PCB may be used in determining the mechanical structure of 3D printer 100; such that, the mechanical structure of 3D printer 100 may vary based on the method used for curing. For example, if “direct curing” is used, by utilizing a laser beam, then a laser head or laser source may be comprised in 3D printer 100, and may follow the 3D-printing head(s) 101 and may cure via a laser beam the material(s) being 3D-printed, substantially immediately upon their 3D-printing; and as a result, a dispensing chamber may not be open, but rather, may be housed or encapsulated or enclosed in order to protect a human operator. In other embodiments, curing may be performed (or hastened, or expedited, or triggered) by modification of barometric pressure in (or by pressurizing of) the dispensing chamber, thereby decreasing the melting temperature; and similarly, the curing method may affect the structure of 3D printer 100.

Curing module 122 may provide, for example: curing by using ultraviolet (UV) light or UV energy or UV radiation, for example, providing electromagnetic radiation with a wavelength shorter than that of visible light but longer than X-rays, or providing electromagnetic radiation with a wavelength in the range of 10 nanometer to 400 nanometer.

Additionally or alternatively, curing module 122 may perform heat-based curing, or curing by using heat or heating; and/or curing by cooling.

Additionally or alternatively, curing module 122 may perform curing by modifying the barometric pressure at, or near, the article being 3D-printed, or in a chamber in which such 3D-printed article is located while being 3D-printed.

In some embodiments that utilize heat-based curing, the curing heat may be applied per the number of layers being 3D-printed, to the entire PCB or circuit board (or the entire article being 3D-printed), or to each and every layer or region or portion (e.g., upon the completion of discharging each such layer or region or portion). The curing heat temperature may vary, based on the material used. The curing module 122 may thus comprise (or be associated with) a heater or heating unit 156, which may be an integral part of 3D printer 100 and may be associated with (or in proximity to) the base 113 where the PCB is being 3D-printed or fabricated on. The 3D printer 100 may allow for encapsulation of the 3D-printed object 199, to prevent the curing heat from effecting the outside environment or surrounding of 3D printer 100; for example, by encapsulating some components of 3D printer 100 in a suitable housing 157. Optionally, venting may be used by 3D printer 100, by using a venting module 158 which may vent such housing 157.

Optionally, in the 3D-printing process, heat may be selectively applied to one or more locations (e.g., isolated locations, or hard-to-reach locations) by using a targeted laser beam, which may be generated by a laser beam generator 159 or other suitable laser beam source. Optionally, screen protective material may encapsulate base 113 or a similar printing table or printing chamber, in order to protect a human operator of 3D printer 100 from being exposed to laser beam(s). The laser beam may allow rapid full curing, or rapid partial curing, and may contribute to achieving dimensional stability in 3D-printing of PCB or circuit or object that have little or no mechanical support.

Optionally, the curing of 3D-printed circuits or PCB or components may utilize UV energy, which may be emitted by a UV energy source 160. The UV energy may be used as a stabilizer (e.g., prior to “baking” the PCB in a PCB baking oven), and/or for curing purposes. The particular wavelength of the UV energy, and the duration of time needed to be used for such UV radiation, may vary based on the 3D-printing material(s) 102 used per circuit.

Optionally, 3D printer 100 may utilize curing via a barometric pressure modification module 161. For example, melting temperature of a 3D-printing material 102 may be modified, increase, decreased or set, based on the barometric pressure that such 3D-printing material is being processed in. In order to allow utilization of a wide range of materials as raw 3D-printing materials, in conjunction with a single dispensing chamber 162 (or a single housing 157), the dispenser chamber 162 itself may be sealed and/or encapsulated, and may allow for different barometric pressure or for a selectively-modified barometric pressure. For example, barometric pressure modification module 161 may increase and/or decrease the barometric pressure in the dispensing chamber 162; and this may, for example, modify the speed in which one or more 3D-printing material(s) 102 melt and/or solidify and/or cure.

Optionally, the 3D printer 100 may perform curing by utilizing a cooling module 163. For example, one or more areas or regions of a 3D-printed PCB may require to be heated up, whereas other areas or regions may require protection from overheating, particularly when a single PCB is being fabricated by utilizing a mixture or combination of multiple 3D-printing materials 102. In a demonstrative implementation, liquid nitrogen may be selectively injected or discharged from the cooling module 163, at particular directions or targets, to selectively protect areas or regions of the 3D-printed object 199 that may not withstand the high temperature associated with curing or dispensing other 3D-printing materials 102.

In some embodiments, any curing or solidifying of the 3D-printed material(s), by any of the above-mentioned methods, or a combination thereof, or other curing methods, may be performed on a layer-by-layer basis, or on a plane-by-plane basis, or on a region-by-region basis; such that, for example, a first layer or plane or region may be 3D-printed, and then may be cured, and then a second layer or plane or region may be 3D-printed, and then it may be cured, and so forth. In other embodiments, additionally or alternatively, the curing may be performed on-the-fly, for example, such that the curing module(s) may follow the 3D-printing head(s) and may perform directed curing or targeted curing of the specific point or small-regions that has just been 3D-printed, or in which 3D-printing material(s) has just been dispensed; such as, a laser beam generator may follow or may move along with the 3D-printing head(s) and may direct a targeted laser towards the recently-dispensed 3D-printing material(s), or such laser beam generator may remain non-moving but may change its orientation or direction or slanting in order to selectively direct the targeted laser beam to recently-dispensed 3D-printed materials; or similarly, a UV energy source may move along with the 3D-printing head(s) or may emit targeted UV energy towards the recently-dispensed 3D-printing material(s), or the like.

In some embodiments, the curing of 3D-printed material(s) is a separate step from, and should not be confused with, a post-printing Baking process in which the entire 3D-printed PCB (or article, or item, or electrical component) may be “baked” (e.g., placed) in a special baking oven for PCBs or electrical components, typically for moisture removal; for example, at a baking temperature of approximately 125 degrees Celsius; at a baking period that can range from a few minutes, to a few hours (e.g., two hours, or four hours), or up to 48 hours. In some embodiments, baking may be performed at a temperature greater than 100 degrees Celsius, to ensure outgassing of water or moisture.

In some embodiments, a 3D-printed PCB may optionally be placed in a Reflow Oven, or machine for reflow soldering of surface mount electronic components to the 3D-printed PCB; without such Reflow Oven damaging the 3D-printed PCB, and such that the 3D-printed PCB stands the heat that such Reflow Oven produces and emits. The reflow oven may be or may comprise, for example, infrared and/or convection oven, vapour phase oven, a multiple heat-zone oven, a reflow oven having one or more heating-zones and/or one or more cooling zones (e.g., with a conveyor belt to move or advance or carry the 3D-printed PCB in accordance with a time-temperature profile), an oxygen-free reflow oven, a nitrogen (N₂) based reflow oven (e.g., to reduce or minimize oxidation of the surfaces to be soldered), or the like.

In conventional systems for fabrication of a PCB, only conductive layers or copper layers are referred to as “layers”; and transition between layers may be achieved by utilizing Vias, which (in a conventional system) are drilled with a drill perpendicularly through multiple layers and then plated with copper in order to conduct electronics signals between different layers of the PCB.

In accordance with the 3D-printing process of the present invention, every step or sub-step in the 3D-printing of the PCB in the Z axis may be regarded as a “layer” by itself, regardless of whether such “layer” is conductive or insulator (or a combination of both). The conventional separation of conductive layers into “Layers” may be redundant in accordance with the present invention, and may be replaced in the present invention by 3D-printed “transitions” or “skipping” or “bridging” or “bridge forming”.

In accordance with the present invention, a “transition” may be 3D-printed when conductive traces need to intersect each other in order to reach their destination as required by PBB design or layout (e.g., the CAD file). The transition region may be 3D-printed, for example, by 3D-printing a first conductive trace; then 3D-printing isolating (or insulating) material over the desired or planned crossing point; and then 3D-printing a second conductive trace over that crossing point, thereby allowing for the signal to intersect but at different Z-axis levels (e.g., in different “heights” vertically), without “shorting” the signal.

In a demonstrative embodiments, a transition/bridge 3D-printing module 164 may be responsible for implementing and 3D-printing such transition or “trace skipping” or “trace bridging”; and optionally, prior to the 3D-printing process, may translate or convert an original CAD layout of the PCB into a corresponding “transition” or “bridge” to be 3D-printed; and may instruct 3D printing head(s) 101 to 3D print, in turns, the suitable printing material(s) 102 in order to form such three-dimensional “bridges” or “transitions” as an integral, embedded part of the PCB being 3D-printed. In some embodiments, such transitions or bridging may be 3D-printed only as needed per the routing requirement(s) of the PCB, as analyzed and “translated” or converted (if needed, from a 2-D format, e.g., from Gerber file format).

Optionally, in some areas or regions of a 3D-printed PCB, there may be multiple transitions in the Z-axis; whereas in some other areas or regions of the same 3D-printed PCB there may be no transitions in the Z-axis. This unique structure may allow a 3D-printed PCB (or an electrical component) to be “multi-layer” in one area or region (or in some regions), while at the same time being “single-layer” in another area or region (or in some, other, regions), or while at the same time having fewer “layers” in other area(s) or region(s). This may be in direct contrast to conventional PCB fabrication, which requires that a constraint of a maximum number of layers would be used in an entire PCB being fabricated, necessarily applying such constraint to the whole PCB in its entirety.

In some embodiments, a via 3D-printing module 165 may be responsible for 3D-printing of (or, for instructing the printing head(s) 101 to 3D-print) one or more vias or Via Equivalents or “blind vias” (e.g., without transitioning, which may require translation from Gerber file format). In some embodiments, Vias need not be drilled and/or plated and/or copper-plated; rather, Vias or Via Equivalents may be 3D-printed by 3D-printing an insulating material(s) around a location that was planned for such “via”, and then 3D-printing conductive material(s) printed into a “barrel” or hole or cavity or vertical tunnel created by an isolating filament.

In some embodiments, a combination of the Via approach and the “skipping” (or transitions) approach may be used; particularly for Ball Grid Array (BGA) packages, or for Via in pad construction.

In a single layer PCB, the 3D printer 100 may start with 3D-printing an insulator layer, which may optionally be applied to a premade insulator to save processing time; and may finish with 3D-printing of the conductor on top of the insulator layer. Alternatively, the 3D-printing may start with no premade isolation material, and the 3D-printing process may 3D-print the isolation material as the base of the 3D-printed PCB.

In a conventional PCB, the Vias are the only way to transition between conductive (copper) layers. The Applicants have realized that Vias may act as stubs or bottle-necks or obstacles in high speed designs, and that there is a need to reduce the Vias size and dimension in the Z axis, and/or to modify the form or structure of a Via.

In accordance with the present invention, which utilizes additive 3D printing, vias need not be used or created, or most vias in a PCB may be avoided; unless the CAD design requires a particular transition of traces that are far along the Z axis. In such case, 3D printer 100 may 3D-print a Via (or a Via Equivalent) that is generally circular or cylindrical, and which may be filled by 3D printer 100 (e.g., with conductive material), or which may remain hollow as a barrel or as a hollow cylinder, or which may be “plated” by 3D-printing of conductive material at the external portions of such barrel (e.g., leaving a hollow interior cavity).

A filled via may be 3D-printed, for example, by 3D-printing insulating material(s) while leaving out a circular shape (or cylindrical shape) for the conductive part to be 3D-printed within. This step may be repeated in the Z-axis, as the build-up of the 3D-printed layers continues upwardly in the Z-axis. The 3D-printing to fill the cavity with conductive material, may be performed on a layer-by-layer basis, namely, every time that the 3D-printing advances (e.g., upwardly) along the Z-axis; or may be performed cumulatively after several Z-axis advancements have been made (e.g., by 3D-printing a conductive material into the cavity). The 3D-printed via, or via equivalent, maybe filled with 3D-printing material(s) that are electrically conductive and/or thermally conductive. In some embodiments, at least 90 or 95 or 98 percent of such Via or Via Equivalent may be filled with 3D-printing materials, thereby avoiding an “air bubble” or trapped bubble(s) which may subsequently explode and cause damage to the via and its surrounding and the entire PCB (e.g., when baked in a baking oven).

In some embodiments, 3D printing may be used to produce 3D-printed equivalents to “blind via” and/or “buried via”. For example, the extent to which a via is 3D-printed in the Z-axis, may determine whether the via being 3D-printed is a 3D-printed “through via” (which runs from the bottom layer to top layer, or vice versa), or a 3D-printed “blind via” or a 3D-printed “buried via”. In some embodiments, there may be no difference in the 3D-printing process in creating buried vias, blind stacked vias, or through vias; and in all cases, drilling may not be required and may not be performed.

Some embodiments may utilize the 3D-printing additive process in order to 3D-print virtually any combination or assembly that includes a 3D-printed Buried Via (or equivalent 3D-printed functional structure), or a 3D-printed Blind Via (or equivalent 3D-printed functional structure); at virtually any location or region or depth in the 3D-printed PCB; between any two (or more) layers or planes or sections of the 3D-printed PCB; in a drill-free process; without utilizing drilling, without utilizing controlled-depth drilling; without utilizing controlled-depth lasering, without utilizing controlled-depth laser ablation; and without limitation of aspect ratio of the diameter-to-depth of any 3D-printed Via or Via Equivalent. In some embodiments, a 3D-printed Via or Via Equivalent may have a diameter of 4 mil, or under 4 mil, or 3 mil, or under 3 mil; and may have a ratio of diameter-to-depth of at least 1:20, or at least 1:25, or at least 1:30, or at least 1:50, or virtually any other desired ratio.

In some embodiments, a hollow via may be 3D-printed, for example, if there is a concern that a filled via might be susceptible to mechanical pressure due to temperature stress. A hollow via may be 3D-printed similarly to a filled via, except that optionally, in the center of the 3D-printed via, a temporary support material may be 3D-printed (e.g., by one of the printing head(s) 101 able to 3D-print temporary support materials); and subsequently, or after the completion of 3D-printing of the PCB, such 3D-printed support material may be removed (e.g., washed away, pulled away, pushed away, vented away, sucked away via suction, blown away with an air push, or the like). In some implementations, the support material may be water soluble, in order to dissolve when the 3D-printed article (e.g., the PCB) is washed with water. This approach may be used, for example, for 3D-printing a hollow via along the entire Z axis (or along most of it), from the top to the bottom of the 3D-printed PCB.

The terms “via” or “via equivalent” as used herein may include any suitable 3D-printed structure, which may be barrel-based or may not resemble a barrel or may not include a “barrel” region of a conventional via; and optionally, may maintain the same form (or shape, or structure, or properties) of the element or component to which such 3D-printed “via” or “via equivalent” is interfacing. It would be appreciated that a 3D-printed via or via equivalent, which may take the same form or shape of the interfaced component or element, may not be achieved by conventional solutions; and may provide various advantages, increased throughput, and reduction of losses and “returns”, thereby increasing the Bit Error Rate (BER).

In some embodiments, some solutions for connecting between traces that are far from each other on the Z axis may be: (a) by 3D-printing of step staggered transitions; (b) by 3D-printing of straight vertical 3D-printed trace; (c) by 3D-printing a trace in the shape of an arc or a curve (or concave element, or convex element). Each one of these solutions may be applied based on the available space for routing and the required durability for mechanical stress.

For example, a step-staggered transition 3D-printing module 166 may be responsible for 3D-printing of a step staggered transition, which may be a demonstrative implementation of moving a conductor in the Z axis from a first location to a second location. The 3D-printed step-staggered structure may improve the mechanical strength of the PCB. Such inter-layer transition may optionally be 3D-printed as a spiral structure or as a helix or helical structure; or by 3D-printing other suitable shape that may improve the routing of signals and/or the mechanical or thermal properties of the 3D-printed PCB or product. In some embodiments, different 3D-printed structure(s) for such transitions may provide different levels of robustness in a certain axis.

In some embodiments, a straight vertical trace 3D-printing module 167 may be responsible for 3D-printing of a straight vertical 3D-printed trace, which may “imitate” a conventional Via (e.g., conventionally produced by drilling a hole from the top layer downwardly). When 3D-printing is used to create a Via Equivalent, the cavity need not be a “barrel” because drilling is not a requirement in order to achieve a connection. Rather, the 3D-printed Via Equivalent may be a continuation of the trace (e.g., such that the 3D printing head 101 may move along the Z-axis, “inside” the 3D-printed PCB that is being 3D-printed, upwardly or downwardly), which may be beneficial for Signal Integrity (SI). In some implementations, high SI may be achieved by 3D-printed embedded coax, as described above and herein. The 3D-printed structure may optionally correspond to an inter-layer via; and may comprise a 3D-printed inter-layer transition of trace between layers while maintaining trace width and/or trace thickness.

In some embodiments, a vertically-curved connection 3D-printing module 168 may be responsible for 3D-printing of concave or convex or arced or curved 3D-printed connections, and may demonstrate the shape freedom provided by the present invention, which may improve SI, mechanical robustness, and/or signal routing. Applicants have realized that in a conventional PCB, the Via point is determined and is fixed for all the layers that the via goes through, and is always perpendicular to the point of transition; and thus, if at a particular point (X,Y) of Layer 5 the signal needs to move downwardly, then the Via goes perpendicularly to Layer 5 and perpendicularly to Layer 4 beneath it, and the trace continues on Layer 4 at the same point (X,Y) beneath the corresponding (X,Y) point of Layer 5 above.

In contrast, the present invention may allow to 3D-print a convex or concave or curved or arced Via Equivalent or inter-layer trace connection or inter-layer transition; such that the slope or slanting or curvature of the inter-layer transition and its direction may selectively determine where exactly the trace will continue. For example, the 3D-printing may allow the trace to “jump” or transition diagonally, from point (X,Y) of Layer 5, to point (X+1, Y+2) of Layer 4, then to point (X+3, Y+3) of Layer 3, and so forth, reflecting a slanted or diagonal or curved or non-linear or non-straight or free-form Via Equivalent or intra-layer trace transition that is enabled by 3D-printing in accordance with the desired 3D-structure.

Some embodiments may support impedance controlled traces, for example, by using an impedance controlled trace 3D-printing module 169. Applicants have realized that due to the repetitive nature of 3D printing, the impedance tolerance of either a single-ended trace or differential pair may be greatly improved. The tolerance and accuracy may be further controlled by having a close loop system controlling the 3D-printing process (e.g., visually). For example, if the trace width for impedance controlled trace needs to be 8 mils (wherein a “mil” is a thousandth of an inch, or, 0.001 of an inch, or 0.0254 millimeters), then 3D printer 100 may start to 3D-print with a nozzle that provides 2-mil accuracy and may 3D-print the trace in four iterations. Due to the tolerance of 3D-printing, a visual inspection module 170 (e.g., comprising a camera able to capture images and/or video, and a controller or processor able to process such images or video and to compare them to the planned design) may determine (e.g., before or during the last iteration; and assuming that the trace line width is observed to still be under 8 mils) where to start the last deposition of material, in order to get as close as possible to the desired 8 mils trace width. In some embodiments, an on-the-fly ablation module 171 may be included or embedded in 3D printer 100, thereby allowing to perform embedded ablation (e.g., on-the-fly embedded Laser ablation) in order to correct on-the-fly, during production time, any deviation from the designed (the required) width of trace(s).

In some embodiments, in a 3D-printed PCB the impedance reference layers (e.g., ground layer or point; or power layer or point) need not necessarily be separated or distinct from other layers (e.g., if there is no requirement to do so by the CAD design). Each reference ground or reference power may be 3D-printed to be located in proximity to the relevant trace(s), for example, in an under or upper layer configuration or in a coax cable configuration. This may reduce the number of layers of the PCB, and may help to isolate ground distance related issues. Optionally, an impedance reference 3D-printing module 172 may be responsible for 3D-printing of ground or power points, regions or locations; and such 3D-printing may be performed on-the-fly and as integral part of the 3D-printing process of the entire 3D-printed PCB.

For example, the reference ground (or reference power) for a specific 3D-printed conductive trace may be 3D-printed as a dedicated ground (or power) reference and may travel through the 3D-printed PCB as such, following the 3D-printed conductive trace (e.g., above it, or under it, or near it). This may not require a dedication of a full plane or full layer in the PCB as a ground layer (or as a power layer), and may thus save space; and may also increase flexibility in the formation of the relevant traces, thereby enabling to modify the trace dimensions as needed while compensating the distance to the dedicated power (or the dedicated ground) to maintain constant impedance along the trace.

Some embodiments may allow 3D-printing of stand-alone impedance control traces. Due to the 3D-printing additive build-up of the PCB, a trace on a given location (on the Z axis) may not need to be referenced to a specific ground or power plan. The ground or power plan to be used as reference for the impedance calculation, may not need to be a plane; but rather, it may be 3D-printed around the trace like a coaxial cable configuration. Furthermore, the distance between the power/ground reference and the trace, may be a stand-alone distance or a fixed distance, based on the required impedance and taking into account conductor thickness and conductor width, without utilizing a layer-versus-layer scheme.

Some embodiments may 3D-print an independent or dedicated region or channel or line or non-straight line or trace-following element or trace-surrounding element, of ground or power, which may functionally operate as reference-ground or as reference-power, for impedance-controlled trace. The 3D-printed reference ground (or reference power) may not occupy an entirety of a horizontal layer or plane; or may occupy less than 100 percent, or less than 95 percent, or less than 90 percent, or less than 80 percent, or less than 60 percent, or less than 50 percent, of the horizontal layer or plane. Optionally, the 3D-printed reference-ground or reference power, may follow the 3D-printed impedance-controlled trace itself, and may be 3D-printed above it or over it; or may be 3D-printed under it or beneath it (e.g., by 3D-printing the reference-ground or the reference-power, prior to 3D-printing the impedance-controlled trace above it or over it or on top of it).

Some embodiments may utilize no lamination (or no lamination press) for layer bonding, and may thus provide a lamination-free (or lamination-press free) 3D-printed PCB having improved control of the dielectric thickness between the ground/power plane(s) and the traces, thereby achieving better impedance accuracy.

In some embodiments, the 3D-printing of PCB may require no lamination; and therefore there may be higher certainty with regard to how much material is left between conductive traces, thereby allowing utilization of thinner dielectrics, and hence also thinner PCB, as well as and higher capacitance in case of insulation required by the PCB design.

Applicants have realized that in conventional systems, a factor that affects the PCB's overall thickness is the number of layers used in conventional PCB fabrication. Applicants have realized that this results from the fact that once a layer is used for a ground, power or signal, such layer occupies space in the Z-axis throughout the entirety of the conventional PCB (e.g., regardless of whether it is required as such through the whole area of the PCB or only at a portion thereof); and thus, the more layers are used, the more the Z-axis dimension of the conventional PCB increases, and the thicker the conventional PCB becomes.

In accordance with the 3D-printing of PCB by the present invention, some embodiments may selectively distribute inter-layer transitions across different horizontal (X-Y) locations of the PCB surface (namely, on the X and Y axes), thereby reducing the impact on the Z axis (the thickness), and allowing to 3D-print such transitions at various horizontal locations. This may be taken into consideration at the CAD stage, and may allow PCB designers to take advantage of this capability that the present invention provides. Optionally, an inter-layer transition placement module 173 may automatically optimize or enhance the distribution of such inter-layer transitions, or may determine or modify the location(s) of such inter-layer transitions, in order to reduce the overall thickness of the PCB, or in order to maintain an overall thickness of the PCB under or within a threshold value.

Furthermore, by using 3D-printing of “transitioning” or “skipping”, signals (traces) may cross each other above the top layer of the 3D-printed PCB, and/or below the bottom layer of the 3D-printed PCB; in regions that are not occupied by components. In such case, the overall bare thickness of the 3D-printed PCB may remain similar to a conventional PCB; but when fully assembled with components that are mounted on the top layer and/or under the bottom layer, the overall thickness of the 3D-printed PCB (with the assembled components) may be smaller when compared to a conventional PCB. For example, the overall thickness may be thinner, because it may not be required to reserve space (for signal skipping or transitioning) on the Z-axis under the components to be assembled; but rather, signal skipping or transitioning may be 3D-printed in between the components to be assembled (or, in between the regions of the PCB onto which such components are to be assembled; and/or in between the components that are already assembled on top of the assembly layer of the 3D-printed PCB). In some implementations, a 3D-printing process of a PCB may be able to introduce a greater number of signal skipping or signal transitions, into the same thickness of PCB (e.g., compared relative to a conventional PCB).

In some embodiments, 3D-printing may be resumed or continued, to 3D-print additional circuitry and/or electronic components, on top of (or over) the planar area of assembly of an already-printed 3D-printed PCB. Applicants have realized that a conventional PCB ends-up at the top with a generally-flat surface for installation or assembly of SMT components; such that the bare PCB thickness is X millimeters, the height of the tallest SMT component is Y millimeters, and thus the overall thickness of the PCB with the SMT components assembled is X+Y millimeters. However, within those top Y millimeters of vertical space, only a small portion of the PCB is actually “occupied” by an assembled SMT component; and other regions of the PCB may be 3D-printed-on, in order to create and run additional trace(s) or routing in those Y millimeters; and optionally, 3D-printing there, on top of the top-most layer of the bare PCB, in regions that are not occupied by SMT components, additional trace(s) or signal routing(s), which may cross or jump over each other using “skipping” or “bridging” and without increasing the overall thickness of the fully-assembled PCB, as long as those small “bridges” or “hills” that are 3D-printed in those reasons are still thinner than the vertical space of Y millimeters that is “protected” by the neighboring SMT component. This may be performed, for example, by a module for 3D-printing over top assembly layer 174, which may identify such available regions on the top surface and may selectively determine which trace(s) or signal(s) may be efficiently 3D-printed there in order to take advantage of a planned SMT assembly of nearby component(s).

In some embodiments, the conducting materials being used for 3D-printing of PCB or electronic component(s), may be or may comprise highly-conductive material(s), or epoxy or resin or ink impregnated (or mixed) with highly-conductive metallic nano-particles or with highly-conductive nano-particles; which may have electrical resistivity in the range of 1.52 to 10 μΩcm, in order to allow loss that is similar to the loss using copper traces. The temperature expansion coefficient of such 3D-printing material(s) may be, for example, between 10 to 12 micro-inch per inch per Fahrenheit degree (e.g., using a temperature range of 68 to 572 degrees Fahrenheit).

In some embodiments, the insulation materials used for 3D-printing of PCBs may vary in their electrical properties, or may have electrical resistivity of 1,000 Mega-ohms per centimeter. In some embodiments, the 3D-printing materials may have a stable dielectric constant and loss tangent.

A conventional PCB includes vias that are barrel shaped, created by drilling along the Z axis. In contrast, in accordance with the present invention, 3D printer 100 may be used for 3D-printing any type of via or micro-via (e.g., a through-hole via or micro-via, a blind via or micro-via, a buried via or micro-via, a thermal via or micro-via, an array of vias or micro-vias), or for creating a suitable 3D-printed transition or structure or “Via Equivalent” which may functionally correspond to a via or a micro-via, for virtually any depth, and independently of aspect ratio, board material(s), pad(s) size, and/or conductive layer thickness.

When 3D-printing a transition between layers, in accordance with the present invention, 3D printer 100 may not be limited to any particular Via shape, but rather, the via shape may be enhanced or optimized for improved circuit functionality and/or circuit structure. For example, high-speed signals may require smooth transition from the pad to the via; and therefore, the 3D-printed via or transition may be 3D-printed in a shape similar to the pad (e.g., rectangular) and does not have to be vertical to the planar pad. Rather, the 3D-printed via or transition may be 3D-printed through the Z axis along a concave route (or curved route, or arced route, or convex route, or non-linear route, or slanted route, or diagonal route, or non-vertical route), to further reduce signal integrity issues which may be associated with Vias. Optionally, a Via Equivalent 3D-printing module 175 may be used to “convert” or optimize or enhance a conventional PCB design, in order to replace a conventionally-planned Via with an enhanced 3D-printed Via Equivalent which may be non-vertical, slanted, diagonal, curved, concave, convex, stairway-shaped, or the like.

Furthermore, in accordance with the present invention, a Via may be designed and 3D-printed as an immediate extension of a trace, and may have the same shielding as the trace, and may have distance from ground to maintain the impedance values of the whole trace. Similar to the ability of 3D printer 100 to 3D-print the ground plan around or near trace(s), the 3D printer 100 may 3D-print the ground plan around or near the 3D-printed Via or Via Equivalent, and may have the trace behave as a coax cable or even as a perfect coax cable. Such unique 3D-printed structure may be referred to herein as “Impedance Controlled Vias”, and may be 3D-printed by utilizing an Impedance Controlled Via 3D-printing module 176 which may be able to determine where to place such Vias and what to 3D-print near or around them.

In some embodiments, the shape or structure of the 3D-printed via or Via Equivalent may be optimized or enhanced for mechanical strength, to improve or optimize space usage, and/or to improve or optimize signal routing or SI. For example, a “stairway via” structure may be 3D-printed, or a diagonal or slanted via may be 3D-printed. In a 3D-printed PCB in accordance with the present invention, the distinction between a via and a trace may become blurred or redundant, since a via (or a transition between two consecutive or non-consecutive “layers”) may be 3D-printed using the same exact shape and form as the trace.

In some embodiments, 3D printer 100 may comprise (or may be associated with) a soldermask 3D-printing module 177. For example, soldermask may be 3D-printed as an integral part of the 3D-printing process of the PCB; and may be cured (e.g., by temperature modification, or by using UV energy). The soldermask may be 3D-printed in layers, and therefore fine resolution may be achieved as UV energy may be used between the 3D-printing of each layer of soldermask; optionally utilizing a pause-and-resume 3D-printing controller, or a 3D-printing ordering module 190.

In other embodiments, 3D-printer 100 may 3D-print a PCB that does not require soldermask; for example, since insulating material or filament may be 3D-printed between pads (e.g., on top of the top layer, and/or underneath the bottom layer), thereby 3D-printing a soldermask-free 3D-printed PCB. For example, 3D-printer 100 may 3D-print an insulating filament over a top layer of the 3D-printed PCB, thereby creating 3D-printed insulating separation between two or more 3D-printed conductive pads; and thereby preventing “shorting” between such pads (e.g., in an assembly process or a surface mount process).

In some embodiments, 3D-printer 100 may comprise a conformal coating 3D-printing module 11 to accurately 3D-print conformal coating on a 3D-printed PCB after SMT assembly (or component assembly, or COB assembly). The 3D-printed conformal coating may be performed after such assembly, to ensure sure that specific areas or regions of the 3D-printed PCB will not “short” even if contacted (e.g., touched) by a conductive object or article. In conventional PCB fabrication, a human user manually applies a masking tape to each region (of each PCB) that needs to remain conductive, and then the PCB is sprayed with a suitable spray, thereby requiring significant time, effort, and human man-power in a manual, tedious, and error-prone process. In contrast, the 3D-printing of the present invention may accurately and selectively 3D-print the conformal coating, exactly over the specific region(s) of the 3D-printed PCB that should be coated (based on the CAD scheme); and may avoid 3D-printing the conformal coating over other region(s) which should remain conductive (based on the CAD scheme), in an automatic 3D-printing process (that may be tape-less or mask-less, or may not utilize masking or taping of PCB regions) that is based on the CAD scheme and does not require a tedious, labor-consuming, and time-consuming manual process.

In some embodiments, 3D printer 100 may comprise (or may be associated with) a 3D-printing material(s) modification module 178, which may enable selective on-the-fly utilization of mixed 3D-printing material(s) in selected locations or regions of the PCB being 3D-printed. For example, 3D-printing material(s) modification module 178 may determine that in a certain region of the PCB being 3D-printed, two or more particular printing materials should be mixed together and discharged, or, a particular 3D-printing material may be used instead of a previously-used other 3D-printing material; and such determinations or modifications may be performed or initiated, for example, to improve or enhance or optimize trace properties, SI, trace thickness, trace width, trace speed, trace loss, or the like.

Some embodiments may comprise an embedded three-dimensional antenna 3D-printing module 179, to allow integrated 3D-printing of a PCB having a built-in or integrated 3D-printed three-dimensional antenna(s), and particularly a three-dimensional horn antenna. For example, an antenna element fabricated by 3D-printing, which may optionally be integrated or embedded in a 3D-printed PCB (e.g., 3D-printed concurrently at a same 3D-printed session), need not be a single-dimensional or two-dimensional antenna; but rather, may be a three-dimensional antenna or a “horn” antenna (e.g., protruding outwardly or externally, in a mushroom shape, from the top layer or the top surface of the 3D-printed PCB); and the addition of the third dimension by using 3D-printing of the antenna element may improve the antenna loss and hence the reception. In conventional PCB fabrication, a horn antenna may not be implemented in a PCB with the same modes of magnetic and electric signal propagation; whereas the 3D-printing process of the present invention may 3D-print a horn antenna that extends or protrudes from the top layer of a PCB upwardly, or vertically, or in the Z-axis. Such 3D-printed horn antenna may have a suitable three-dimensional structure, for example, pyramidal horn, sector horn, E-plane horn, H-plane horn, conical horn, exponential horn, corrugated horn, ridged horn, septum horn, aperture-limited horn, mushroom-shaped horn, or the like.

Some embodiments may utilize an embedded open cavity/air void 3D-printing module 180, to allow 3D-printing of a PCB having a built-in or integrated 3D-printed open cavity or aid void. The open cavity may be an area inside the PCB that is enclosed with conductive material or with isolating material (depending on the application or requirements). The 3D-printing process may avoid 3D-printing any material(s) in such void-intended region; but rather, may only 3D-print a “hollow box” or frame around it, thereby creating the desired void. Such 3D-printed “void” may be utilized for various purposes, such as, for a waveguide, if the void is enclosed in a conductive “box” or cube, or Radio Frequency (RF) filter, or microwave filter, or millimeter wave filter, or the like.

Some embodiments may allow 3D-printing of circuitry on uneven surface. A conventional PCB is planar in nature, due to the layering process of its fabrication. In contrast, the 3D-printing process may not be restricted to producing planar PCBs, but rather, may utilize an additive process which may allow a PCB designer to create any desired shape or structure, including non-planar structure(s). A circuit or PCB may be 3D-printed as a stand-alone circuit which may be shaped as a barrel, or cylinder, or box, or sphere, or half-sphere, or a slanted or curved structure, or a stairway-shaped structure, or a slope, or other suitable structure which may accommodate a particular purpose or device. Optionally, the circuit may be 3D-printed onto an existing article or material (e.g., vehicular head lights).

Some embodiments may allow 3D-printing of additive layer build-up with integrated or embedded or simultaneous Automatic Optical Inspection (AOI), via an on-the-fly AOI module 187 which may be comprised in 3D printer 100 and may be integrated therein. The on-the-fly AOI module 187 may verify in real time that 3D printer 100 is indeed 3D-printing with the required accuracy and that there is no deviation from the predefine operation due to tolerance drift or malfunction. The on-the-fly AOI may be performed with reference to a “gold unit” or the actual Gerber file. The AOI module 187 may measure with sufficient accuracy the line width that is actually being 3D-printed; and if the line width is off (e.g., by a mil, or by several mils), then the AOI module 187 may trigger a remake of the 3D-printing operation in that particular trace or region, such as, to add more width to a recently-3D-printed conductive line. The AOI module 187 may also detect predefined conditions which may be associated with potential failure; and in response, 3D printer 100 may redo the entire 3D-printed article (or, may re-do a portion thereof, or may amend a portion thereof); or may suggest to a human operator to fix (touch up) manually, or may allow a human operator to stop the 3D-printing process and scrap the material(s) and avoid wasting more time and more materials on a failed unit. In some embodiments, the AOI module 187 may inspect every signal in each “layer” (or region) and may ensure that it looks acceptable based on a predefined standard.

In some embodiments, the AOI module 187 may detect other types of defects in 3D-printed PCB or component, and may trigger a corrective cycle module 193 to perform a corrective cycle or corrective action or corrective 3D-printing, and/or may trigger ablation or laser-based ablation or etching or other suitable corrective operation(s) to remedy such identified defect(s). For example, the AOI module 187 may identify that a 3D-printed trace as a fracture or other defect, and may trigger a 3D-printing corrective cycle to specifically re-do or re-print a small portion or region of the 3D-printed trace in which the defect or fracture was identified.

In another example, the AOI module 187 may visually inspect and analyze image(s) of 3D-printed pads or “lands”, which are elements located typically on the outer surface of the 3D-printed PCB and to which component leads are mechanically and electrically fixed, e.g., with molten metal solder; the 3D-printed pads or lands being 3D-printed by a pads 3D-printing module 194. The AOI module may determine that a 3D-printed pad is too small or too big or too thick, or is excessively large such that it “spills” and touches a neighboring pad (thereby “shorting” the circuit); and this may trigger a corrective cycle, for example, to 3D-print additional materials if the 3D-printed pad is too small, or, to perform ablation or laser-based ablation if the 3D-printed pad it too big or too wide or “spills” towards a neighboring pad.

In some embodiments, 3D printer 100 may comprise, or may be associated with, a verification module 14, for example, to ensure that the 3D-printed PCB (or electrical component) conforms to a functional specification or formal specification. Verification module may perform electronic testing (“E-testing”) or conductivity testing, on a 3D-printed PCB or on a partially-3D-printed PCB. In some implementations, the verification module 14 may perform conductivity testing to verify that all points on the 3D-printed PCB, that were intended to be inter-connected, are indeed inter-connected.

In some embodiments, the verification module 14 may comprise (or may utilize) a “flying probe”, having two or four heads, able to hover over all the nets (connection points) of the 3D-printed PCB and to check conductivity among points or nets that should be inter-connected. In some implementations, the verification module 14 may be an integral or internal or embedded or integrated part of the 3D-printer 100, thereby allowing a user to utilize 3D-printer 100 in order to 3D-print not only a 3D-printed PCB, but also a conductivity-verified 3D-printed PCB, such that the verified 3D-printed PCB may be used immediately upon its removal from the 3D-printer 100.

Some embodiments may comprise an embedded heat-sink 3D-printing module 181, able to 3D-print a heat sink (e.g., a thermally-conductive heat sink) integrated or embedded or built-in within (or as part of) the 3D-printed PCB. For example, certain locations or components of a 3D-printed PCB (e.g., under a 3D-printed conductive pad) may require heat transfer path with greater heat conductivity. By using 3D-printing, the material which is 3D-printed under these predefined areas may be material having higher thermal conductivity than the regular or surrounding isolating material used to construct the PCB (or other regions thereof), as determined and/or implemented by a thermal conductivity planner 187. If the routing allows, then under these components or regions, the 3D-printing may be performed with a thermally-conductive material (and/or electrically-conductive material) all the way downward to the bottom side of the 3D-printed PCB, to allow improved or optimal heat path to a thermally-conductive heat sink.

Some embodiments may utilize an embedded COB/SMT component 3D-printing module 182, to enable 3D-printing of a 3D-printed PCB having a partially or entirely covered or buried Chip-On-Board (COB) component; or 3D-printing of a PCB having a partially or entirely covered or buried Surface-Mount Technology (SMT) component. For example, a 3D-printing process of a PCB may be intentionally paused or stopped or interrupted, in order to perform assembly operations of a COB or SMT component or layer on top of an already-3D-printed (or partially-3D-printed) portion or region of the PCB being 3D-printed; and then, after such COB/SMT component assembly, the 3D printer 100 may resume the 3D-printing of the PCB on top of (and/or in horizontal proximity to) the assembled COB/SMT component or layer. Some implementations may thus allow construction of a multi-dimensional COB/SMT on a single PCB, using intentionally paused-and-resumed 3D-printing with COB/SMT assembly being performed between 3D-printing sessions (optionally utilizing a pause-and-resume 3D-printing controller 188; and optionally utilizing a COB/SMT component assembly sub-system 189).

Some embodiments may provide 3D-printing of PCB that allows adaptive trace dimension while maintaining constant (fixed, non-varying) current-carrying capacity; by utilizing an on-the-fly trace thickness/trace width modifier 183 able to modify, in real time and while 3D-printing of a trace, the width and/or the thickness of the conductive material being 3D-printed while maintaining constant (fixed, non-varying) current-carrying capacity.

Applicants have realized that conventional PCB production may have routing requirements and/or pad geometry that may force, for example, a six-mil trace (width); and in order to carry a 2-Ampere current, the required copper thickness may be 3 Oz, and this copper thickness must be kept anywhere that this signal goes and on any layer of the PCB, thereby increasing the cost of the conventional PCB, and/or preventing from using components with finer pitch on that board (since the 3 Oz copper thickness is a limiting factor in etching). Applicants have further realized that in conventional PCB production, an attempt to modify copper thickness or the trace width will “penalize” the resulting PCB by causing an undesired modification of the current carrying capacity.

In contrast, some embodiments of the present invention, for example, may 3D-print a six-mil trace (width) at virtually any desired thickness; and once the signal reaches an area where it does not necessarily have to be 6 mils, the 3D-printing process may increase the width of the 3D-printed trace and may reduce the copper thickness there; such that the current carrying capacity of the signal may remain the same (e.g., 2 Amperes in that example), while the width and thickness dimensions of the trace may change. It would be appreciated that these features and capability of the present invention may not be possible in conventional PCB fabrication, and may provide great benefit to PCB designers and/or PCB manufacturers.

Some embodiments may allow 3D-printing of a PCB having hybrid properties of rigidity and flexibility, or a PCB having varying flexibility or semi-flexibility. Applicants have realized that conventional PCB production was able to produce only the following types of boards: (a) an entirely rigid PCB; (b) an entirely flexible PCB; (c) a rigid-flex PCB, in which an entirely-rigid region is attached to an entirely-flexible region; (d) a flexible PCB having a stiffener in one or more particular regions thereof. It would be appreciated that these features and capability of the present invention may not be possible in conventional PCB fabrication, and may provide great benefit to PCB designers and/or PCB manufacturers.

Applicants have realized that in conventional PCB production, a flexible (“flex”) PCB is formed of a flexible material that is applied throughout the entire layer of the PCB; and as a result, the mechanical flexibility of a Flex PCB is the same throughout the entire PCB.

In accordance with the present invention, the 3D-printer may selectively enhance a 3D-printed PCB by 3D-printing a mixture or materials that have different flexibility properties or different rigidity properties; and optionally, rigidity may be added or increased by selectively adding more thickness to a conductive layer being 3D-printed. Accordingly, a rigidity/flexibility modifier sub-unit 184 may be used by 3D-printer 100 in order to 3D-print a PCB which may be flexible (“flex”) at a first region, and then, other, continuous, region(s) of the same PCB may be rigid, or stiff, or semi-flex; or a PCB having gradually-changing level of rigidity or stiffness or flexibility. In some embodiments, a single 3D-printed PCB may have varying levels of flexibility or rigidity, or a gradually-changing or gradually-increasing or gradually-decreasing level of flexibility or rigidity, or a non-abruptly-changing level of flexibility or rigidity, by selectively utilizing different ratios or proportions of 3D-printing materials, or by gradually (or abruptly) modifying the ratio of 3D-printing materials being discharged or mixed or used.

This may allow various advantages, for example: (a) particular regions or location of the 3D-printed PCB may be selectively stiffened or hardened, in order to facilitate component placement there; (b) areas of concern for breakage may receive increased mechanical support; (c) more routing options may be achieved, particularly for high-power/high-current traces where the innovative features of “adaptive current-carrying capacity” (as described herein) of the traces may be utilized, for example, to make traces wide in a location that requires flexibility and bending, and then increase conductor thickness where routing space is limited without compromising on (or degrading) the product functionality or the current-carrying capacity; (d) ability to 3D-print a semi-Flex area, where flexibility is required but some rigidity would enhance the product's life.

For example, a semi-flex 3D-printing controller 185 may manage and control the 3D-printing process to achieve such advantages. The semi-flex approach may be implemented, for example, by selectively 3D-printing polyamide materials mixed with FR-4 epoxy resin in different thickness in various regions or locations of the PCB being 3D-printed. Furthermore, the resulting 3D-printed PCB may not necessarily be flat or planar, and this by itself may be an advantage that conventional PCB production lines may not achieve (due to, for example, the conventional need for lamination and the fact that a conventional PCB is processed in sheets and layers.)

The 3D printer 100 may optionally comprise a Z-axis balancing module 186, able to balance (relative to the Z-axis; relative to a vertical line; relative to a line perpendicular to the ground or earth surface) the 3D-object being 3D-printed during the 3D-printing process. For example, the 3D printing process may result in an interim situation in which a left-side region of the PCB being 3D-printed is heavier, or significantly heavier, than the right-side region of the PCB being 3D-printed, due to difference in the number of “layers” that were (so far) 3D-printed in each region, or due to the difference in 3D-printing material(s) that were 3D-printed in each region.

In some implementations, “balancing weights” may be 3D-printed or may be temporarily placed in particular locations or regions (e.g., specific corners) of the PCB being 3D-printed, to contribute to its balancing. In some implementations, the balancing module 186 may check the Z-axis balancing the PCB on-the-fly while it is being 3D-printed (or after it is 3D-printed), and if needed, will cause 3D-printing of such “balancing weights” to improve or restore the balance; or may make other adjustments to the 3D-printing process (e.g., modify the order in which regions are 3D-printed; modify a curing time between 3D-printing iterations or sessions; modify the 3D-printing material(s) being used). In some implementations, the balancing module 186 may evaluate the design in advance and may determine in advance, which 3D-printing operations or modifications to apply in order to improve or optimize the balancing of the PCB that is intended to be 3D-printed.

Some embodiments may utilize a filament 3D-printing module 197 to 3D-print one or more suitable types of filaments as insulator or as electrically-insulating component; having the ability to tolerate heat of 260 degrees Celsius for three minutes without suffering internal movement. The 3D-printed filament material(s) may have, for example, the following demonstrative characteristics: (a) curing temperature of approximately 110 to 170 degrees Celsius; (b) adhesion to conductive material, to achieve a peel strength of approximately 0.8 to 2 N/mm; (c) having relative permittivity or dielectric constant (DK) (e.g., at room temperature under 1 kHz) of approximately 2.2 to 12; (d) having Dissipation Factor (DF) of approximately 0.0018 to 0.04; (e) having Coefficient of Thermal Expansion (CTE) of approximately 8 to 18 ppm per Celsius degree; (f) having Volume Resistivity (or electrical resistivity, or specific electrical resistivity) of 0.5×10⁶ MΩ/cm; (g) having Surface Resistivity in the range of 0.5×10⁶ MΩ to 2×10⁶ MΩ; (h) having thermal conductivity of approximately 0.25 to 7 Watt per meter kelvin. Other suitable ranges or values me be used.

Some embodiments may determine which value(s) to select or utilize, for example, by taking into account a possible trade-off between parameters, or in order to achieve particular design goals or functional goals. The 3D-printed materials for filament may be selected by taking into account electrical performance, process computability, price, and/or other factors.

In some embodiments, the 3D-printed material may be equivalent (e.g., electrically, mechanically) to FR-4 material(s) having glass-transition temperature (Tg) of 130 degrees Celsius, of 170 degrees Celsius, of other Tg value in the range of 130 to 170 degrees Celsius.

In some embodiments, the filament may be applied to a 3D-printed PCB by one or more suitable methods, for example: as paste through a 3D-printing or dispensing head; as liquid through a spraying head; or the like. The viscosity of each type of filament may determine which 3D-printing (or dispensing) head to use, or which nozzle to use, as well as the resolution and minimum layer thickness that may be applied. The matching of conductive and filament 3D-printed materials may be important for the successful operation of the 3D-printed PCB once fully 3D-printed and assembled.

Some embodiments may utilize particular materials and/or techniques, in order to adhere or attach the 3D-printed metal parts or regions or elements, to the 3D-printed insulator parts or regions or elements. The adhesion between the insulating 3D-printing materials and the conductive 3D-printing materials may be important, since the top and bottom layers may be used to place components directly to the pads. The pads may be implemented by 3D-printing of conductive material on top of insulating material. The strength of the adhesion may be known as “peel strength”; such that different materials may have different “peel strength” and hence may be more favorable for use with specific components.

Some embodiments may perform 3D-printing of conductive materials and insulating materials to achieve peel strength of approximately 4 to 7 lbs/inch; taking into account the thickness of the conductive layer, as well and the process the 3D-printed PCB may go through after its 3D-printing is complete.

Some embodiments may ensure that there will be no chemical or metallurgic interaction between the conductive material and the isolation material, as such interaction may (undesirably) modify their properties. In other embodiments, conversely, chemical or metallurgic interaction between the conductive material and the isolation material may be allowed, and may even be utilized by such implementation, for example, in order to contribute to adhesion of regions or components, structural stability and strength, or the like.

Adhesion may be a factor also for traces and not only pads, for example, when a flexible or semi-flexible PCB is 3D-printed. The thermal expansion coefficient of the 3D-printing material(s) may also affect the quality of the bonding between the materials.

Optionally, a dielectric material thickness adjustor 191 may be utilized in 3D-printing of a PCB, for dynamic (on-the-fly, while 3D-printing) or pre-planned adjustment (or modification) of the thickness of 3D-printed dielectric material, at virtually any given point or region of the 3D-printed PCB, or between each and every pair of layers being 3D-printed; and may allow to 3D-print a PCB having different or varying thickness of dielectric material between layers, or having gradually-increasing or gradually-decreasing thickness of thickness of dielectric material between layers, or having other non-fixed or varying thickness of dielectric material between layers.

Optionally, a non-parallel layer 3D-printing module 192 may be used to 3D-print conductive material(s) in a three-dimensional structure of non-parallel layers (e.g., as demonstrated herein). For example, the non-parallel layer 3D-printing module 192 may 3D-print: (A) a first 3D-printed conductive layer, and (B) a second, neighboring, non-parallel, 3D-printed conductive layer; and may operate in conjunction with a compensating module 195 which may compensate for non-parallelism of the first and second 3D-printed conductive layers, for example, by modifying a thickness of a 3D-printed dielectric material between the first and second 3D-printed conductive layers, and/or by modifying a width of the 3D-printed conductive trace (in order to maintain constant impedance of the 3D-printed trace, along the trace propagation, even though the thickness of the 3D-printed dielectric material may be varying and non-constant) For example, the compensating module may modify a width of a 3D-printed trace in order to maintain a constant impedance of the 3D-printed conductive trace in regions having different thickness of the 3D-printed dielectric material.

The present invention may provide or may allow, for example, 3D-printing of, and utilization of, uneven stack-up PCBs. A conventional PCB is stacked-up with layers; and the thickness of the dielectric material between layers, and the thickness of the conductive layers, may be dictated by the PCB design. The Applicants have realized that the PCB design may have conflicting requirements or constraints, for example, trace width limitation on control impedance signals versus overall board thickness or value of embedded components.

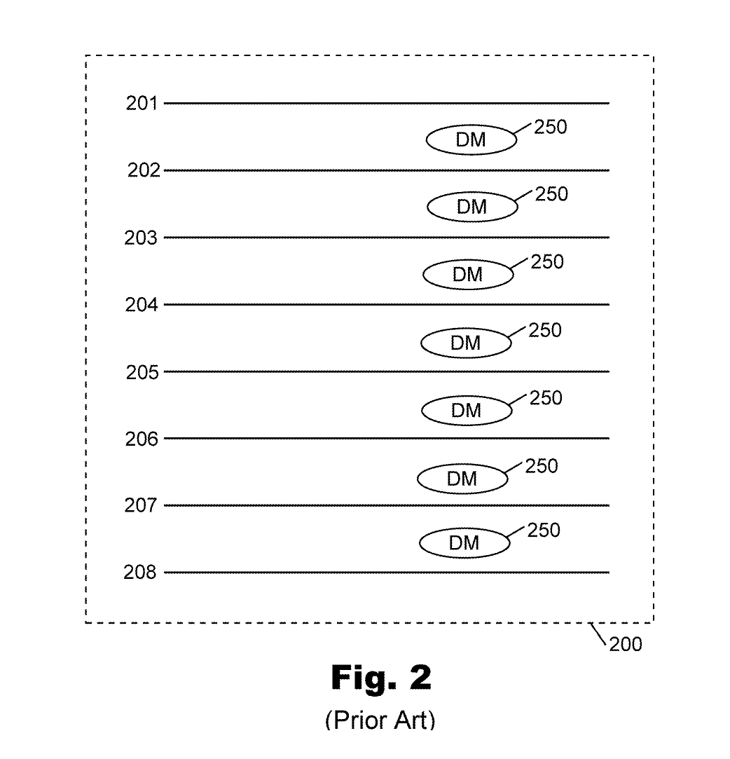

Reference is made to FIG. 2, which is a schematic illustration of a side-view of a prior art PCB 200 having even stack-up of layers. For example, eight layers 201-208 of conductive material are parallel to each other; with Dielectric Material (DM) 250 occupying a fixed, constant, inter-layer thickness between each pair of neighboring layers. In the prior art PCB 200 shown in FIG. 2, the thickness of the dielectric material 250 between each pair of conductive layers is constant and non-varying.

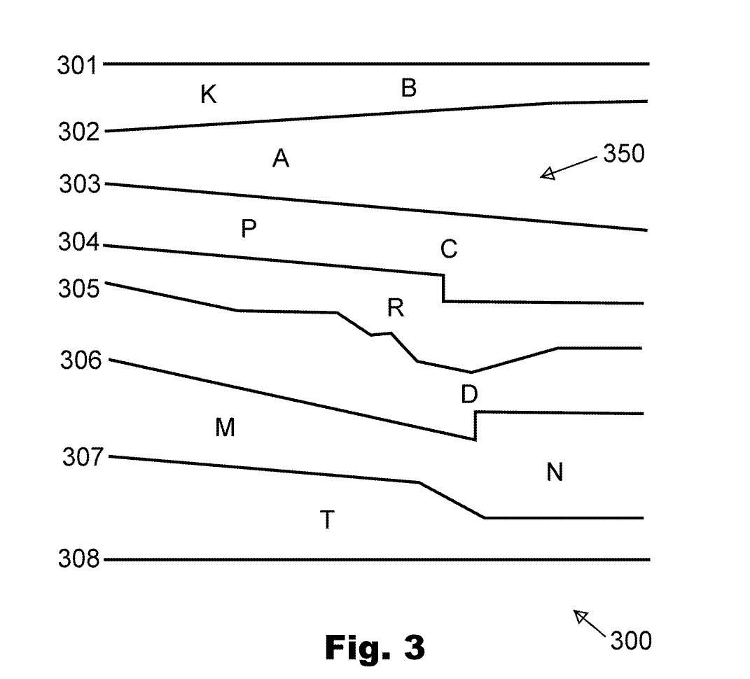

Reference is made to FIG. 3, which is a schematic illustration of a side-view of a 3D-printed PCB 300 having uneven stack-up of non-parallel layers, in accordance with some demonstrative embodiments of the present invention. For example, eight layers 301-308 of 3D-printed conductive material are not necessarily parallel to each other; the layers 301-308 or regions thereof may be partially parallel to each other (e.g., region “P”), and partially non-parallel to each other (e.g., region “K”). Dielectric material 350 between each pair of consecutive (or neighboring) layers may have non-constant or non-fixed thickness, or varying thickness (region “R”), or gradually-increasing thickness (region “A”), or gradually-decreasing thickness (region “B”), or abruptly-increasing thickness (region “C”), or abruptly-decreasing thickness (region “D”). Accordingly, the entire stack-up of layers 301-308 may have varying thickness, or varying dielectric thickness, in different locations or regions or areas of 3D-printed PCB 300. For demonstrative purposes, dielectric material 350 is depicted between layers 302 and 303; however, the same dielectric material, or other dielectric materials, may be 3D-printed or dispensed between other layers, or at other regions of 3D-printed PCB 300.

This may be achieved by using the 3D additive process of the PCB build-up, which may discharge varying and non-uniform amounts or thickness of 3D-printing material(s) (for example, dielectric material, conductive material) in different locations along the X-Y axes, thereby creating non-uniform Z-axis properties or “heights”, as well as slanting, slopes, curves, non-horizontal regions, non-planar regions, or other suitable structure.

In addition to the varying or non-fixed thickness of dielectric material between conductive layers, the 3D printing process of PCB may allow different materials with different dielectric constants to be mixed and discharged. For example, a first region (region “M”) of dielectric material between two particular neighboring layers may include a first dielectric material; whereas a second region (region “N”) of dielectric material between those two layers (or between another pair of layers in the same 3D-printed PCB, region “T”) may include a second, different, dielectric material, or may include a mix of one or more materials (which may include, or may not include, the first dielectric material).

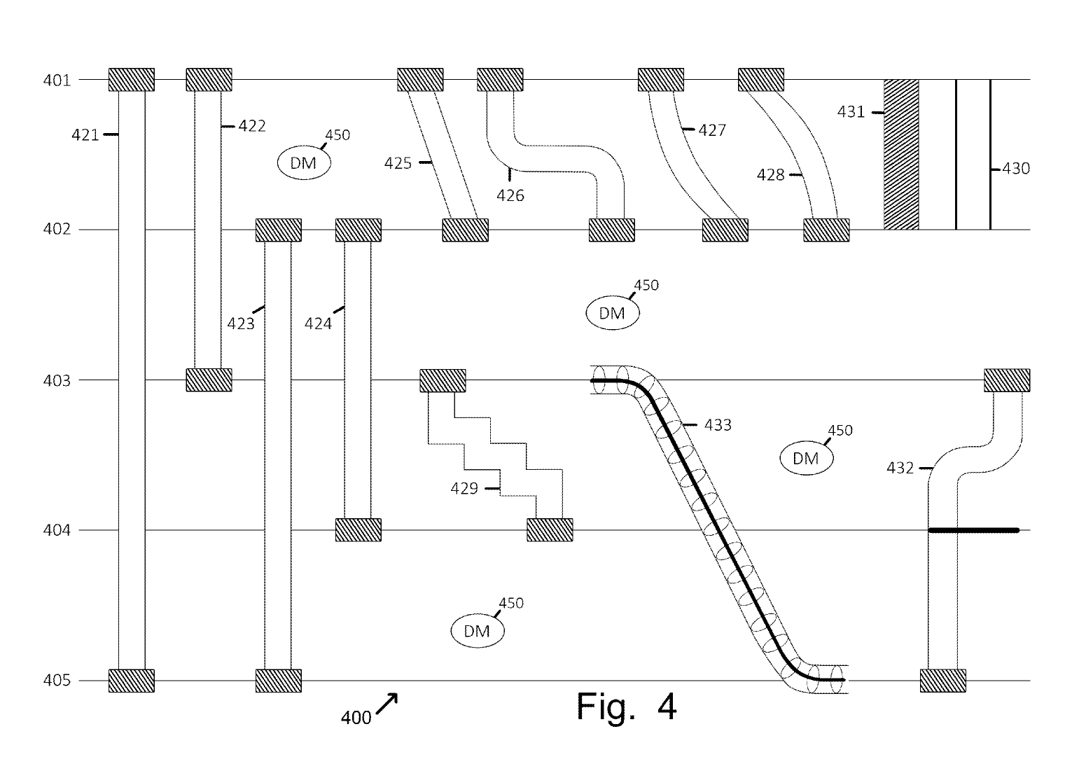

Reference is made to FIG. 4, which is a schematic illustration of a cross-section of a 3D-printed PCB 400 in accordance with the present invention, demonstrating multiple 3D-printed vias 421-433 (or 3D-printed Via Equivalent structures) which may be 3D-printed in accordance with the present invention. For demonstrative purposes, PCB 400 may comprise multiple “layers” 401-405 (or planes, or regions) of conductive material; and optionally, dielectric material 450 between each pair of neighboring layers.

3D-printed Via 421 may be a through-hole via or micro-via, or a Plated-Through Hole (PTH).

3D-printed Via 422 may be a blind via, in which a top region of the via is exposed, whereas a bottom region of the via is unexposed.

3D-printed Via 423 may be a blind via, in which a bottom region of the via is exposed, whereas a top region of the via is unexposed.

3D-printed Via 424 may be a buried via, in which a top edge of the via is unexposed, and a bottom edge of the via is unexposed.

3D-printed Via 425 may be a slanted via, or diagonal via, or slanting via, or non-vertical via. Optionally, the 3D-printed Via 425 may conform to the dimensions (width, thickness) of the 3D-printed conductive trace dimension(s) and may allow a smooth inter-layer transition of the 3D-printed conductive trace.

3D-printed Via 426 may be a curved via, or non-straight via, or non-linear via, or arced via.

3D-printed Via 427 may be a concave via.

3D-printed Via 428 may be a convex via.

3D-printed Via 429 may be a stairway via, or a stairway-shaped via; having a unique structure which may contribute to mechanical stability or may provide other desired properties; demonstrating form flexibility for structure optimization and/or for routing optimization.

3D-printed Via 430 may be an empty via, or hollow via, or non-filled via.

3D-printed Via 431 may be a filled via or plugged via, for example, filled with electrically-conductive material(s) and/or thermally conductive material(s). In some implementations, at least 90 or 95 or 98 percent of the volume of Via 431 may be filled, thereby avoiding an “air bubble” or “gas bubble” (which may subsequently explode and damage its surrounding).

3D-printed Via 432 demonstrates a Via transition in the middle of (or within) the dielectric material 450. For example, a 3D-printed stacked via may be implemented, and the via itself may be vertical at some points, or may turn horizontally (or in a curved manner) and then continue vertically again.

3D-printed Via 433 demonstrates a full, smooth, coax-form transition between layers with shielding and full inter-layer continuity (or, with no inter-layer discontinuity). For example, an inter-layer 3D-printed Via Equivalent may be a conductive trace having coaxial insulation around it, running between “layers” without the need for a via. The 3D-printing of the present invention may keep the conductive trace references to power or ground, not only when the conductive trace runs horizontally, but also when it runs vertically or diagonally (e.g., slanted, or between layers). As demonstrated, the 3D-printed conductive trace may be surrounded by 3D-printed dielectric material, and then surrounded by conductive insulation (e.g., a mesh or a solid conductive material encircling around the conductive trace but not touching it).

In some embodiments, a 3D-printed via may begin from within a 3D-printed pad (or land), and may be implemented as a 3D-printed via-in-pad; or, a 3D-printed via may be connected to a 3D-printed conductive trace. Optionally, a stacked via or a plugged via may be 3D-printed; and a 3D-printed via may have a high aspect ratio of via-depth to via-diameter (e.g., at least 25:1 ratio).

As demonstrated, Via equivalents or inter-layer transitions may be 3D-printed, without suffering from the vertical-only constraint of a conventional drilled via. The 3D-printing may allow sequential or continuous creation of the via or transition, inherently within the 3D-printing process that fabricates the 3D-printed PCB; thereby allowing to maintain or enhance electrical performance, while providing three-dimensional options to optimize routing.

Some embodiments may provide 3D-printing of PCB and electronic component(s) without the need to create and/or to utilize a mold or a template; without necessarily utilizing or depositing soldermask; without electro-plating; without utilizing lithographic mask or reticle; and/or without a subtractive step in which materials are removed or etched away or cut away.

Some embodiments may optionally utilize laser sintering to form three-dimensional structures of desired shapes. Such technique may include: spreading loosely compacted powder or particulate matter evenly onto a flat surface (e.g., utilizing a roller); the thin particulate layer is then raster-scanned with a high-power laser beam; the particulate matter that is struck by the laser beam is fused together; whereas areas not hit by the laser beam remain loose. Successive layers may be deposited and raster-scanned, one on top of another, until the entire structure is complete. Each layer may be sintered to a sufficient degree, to ensure its bonding to its preceding layer.

Some embodiments may utilize other suitable three-dimensional printing techniques which may use an inkjet stream of fluid to create 3D objects under computer control, in a manner partially similar to the way an ink-jet printer produces two-dimensional graphic printing. For example, a metal, metal structure, conductive structure, metal alloy or metal composite part may be produced by 3D-printing of liquid metal(s) to form successive cross sections, one layer after another, to a target using a cold welding (e.g., rapid solidification) technique, which causes bonding between the particles and the successive layers. Other suitable fluids may be, for example, fluids containing a conductive material such as metallic nanoparticles optionally functionalized or encapsulated by organic moieties; or a fluid containing a conductive precursor such as organometallic compounds.

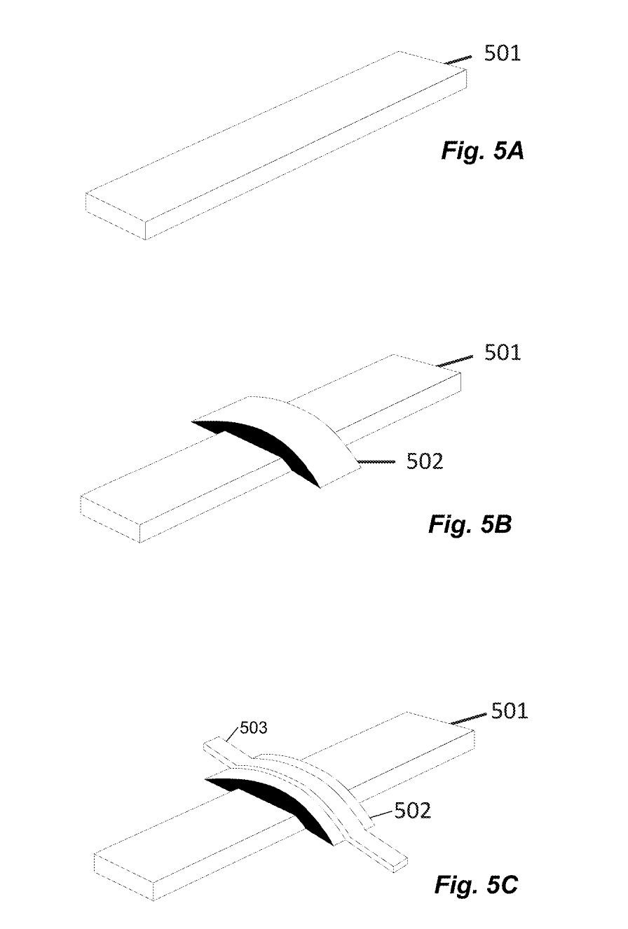

Reference is made to FIGS. 5A-5C, which are schematic illustrations demonstrating 3D-printing of “trace skipping” or “trace bridging”, in accordance with some demonstrative embodiments of the present invention. As demonstrated in FIG. 5A, a first conductive trace 501 may be 3D-printed from conductive material(s). Then, as demonstrated in FIG. 5B, an electrically-insulating (or electrically-isolating, or resistive, or non-conductive) bridge element 502 may be 3D-printed, from non-conductive material(s), on top a particular region of conductive trace 501; in a bridge-shape structure, or an upside-down “U” shape, or in an “n” shape, or the like. Then, as demonstrated in FIG. 5C, a second conductive trace 503 may be 3D-printed from conductive material(s), in a direction that may cross the long dimension of trace 501 (or, such that trace 503 may be generally perpendicular to trace 501); however, conductive trace 503 may not touch conductive trace 501, but rather, conductive trace 503 may pass over the bridge element 502 which isolates between trace 501 and trace 503, and allows the two traces 501 and 503 to “cross” each other without shorting.

It is noted that bridge element 502 may have other suitable structure(s), and that bridging or skipping of 3D-printed traces may be performed in other methods. In some embodiments, the bridging or skipping may be performed multiple times, at the same spot or region or in different regions. For example, another insulating bridge element may be 3D-printed on top of another region of conductive trace 501, in order to allow a third conductive trace to traverse thereon. In another implementation, another insulating bridge element may be 3D-printed on top of the same region that already contains the bridge element 502, thereby allowing a “vertical stacking” of traces and bridges, one on top of the other.

Applicants have further realized that conventional systems and methods for manufacturing of products and for the sale and shipping of such manufactured products, may be inefficient and may be improved by utilizing 3D-printing.

Applicants have realized that in a first conventional system and method of manufacturing/marketing, a manufacturer may, for example, produce a product (e.g., a laptop computer), and may then market and sell the fabricated laptop (e.g., by displaying the laptop at a retail store). Applicants have realized that such conventional system and method may suffer from multiple deficiencies; for example, the need to maintain and store an inventory of fabricated products, and the risk of manufacturing the product which may then not be purchased at all (e.g., since the market has advanced to a newer technology).

Applicants have further realized that in a second conventional system and method of manufacturing/marketing, a manufacturer may, for example, firstly market a product (e.g., a laptop computer), and only upon receiving a purchase order from a consumer, the manufacturer may proceed to purchase from third-parties the various components required for such manufacturing, and to assemble the product from such purchased components. Applicants have realized that such conventional system and method may be imperfect, since the manufacturing process may require a length time period (e.g., several days) for purchasing and obtaining the required components from domestic or foreign suppliers, and then assembling the final product; thereby delaying, sometimes significantly, the delivery of the product to the consumer.

Applicants have realized that an improved system and method of manufacturing/marketing may be used, benefiting from the unique capabilities of 3D-printing. For example, in accordance with the present invention, a retailer (e.g., Amazon) or a manufacturer (e.g., HP) may utilize a 3D printer in order to 3D-print, locally, a product that is offered for sale; and such 3D-printing of the product may be performed, for example, prior to offering the product for sale, or while the product is being offered for sale, or after the product is being offered for sale, or even after the product is actually purchased by a consumer (e.g., in an online purchase transaction).

In a demonstrative embodiment, a retailer (e.g., Amazon) may locally 3D-print a product and may then sell the product online; and such local 3D-printing may substitute procurement of the product from third-party sources, domestic or foreign. In another implementation, the retailer (e.g., Amazon) may generally procure the product by purchasing the product from a third-party supplier; but, when the retailer's system detects that inventory of the product is low or reaches zero (or, is about to reach zero within a pre-defined number of hours or days), the system of the retailer (e.g., Amazon) may automatically initiate local 3D-printing of the product that is low on inventory, in order to substitute for the procured product while more items are on their way from the remote supplier to the retailer.

In another demonstrative embodiment, a retailer (e.g., Amazon) may advertise for sale on its website, a product that is not currently in the retailer's inventory at all, and that the retailer may not necessarily intend to procure from third parties; and, only after a consumer purchases the product, the retailer (e.g., Amazon) may locally 3D-print the product, rapidly (e.g., within 30 to 60 minutes), and may rapidly ship it to the consumer (e.g., by mail, by courier, by truck, by air; or by a dedicated drone or Unmanned Aerial Vehicle (UAV) or robotic device capable of efficient and/or rapid delivery from the retailer to the consumer).

The term “metal” as used herein may include, for example, a single metal; a plurality of metals, or multiple metals; an alloy of metals; a mixture of metallic particles (or micro-particles) from two or more metals; a mixture of metallic nano-particles from two or more metals; a mixture of alloys; a mixture or solid solution of two or more metals; a mixture or solid solution of one or more metals with one or more other element(s); a homogenous mixture or alloy; a hetrogenous or non-homogenous mixture or alloy; an inter-metallic compound (e.g., having two or more pure metals); or the like.

The term “die” as used herein may include, for example, a small block of semiconductor material, on which a circuit may be fabricated. In a conventional system, Integrated Circuits (ICs) are typically produced in mass quantity (e.g., and not one-by-one, and not discretely) as an array of ICs located on a single semiconductor wafer; the array is separated or cut or sliced into pieces, each such piece being a “die” containing a copy of the IC.

The term “particulate matter” as used herein may include, for example, liquid and/or solid material(s) that exist or existed in the form of minute separate particles or as discrete particles, e.g., as a powder or as aggregated granules, or as micro-particles or nano-particles.

The term “semiconductor” as used herein may include, for example, one or more substances (e.g., solid substances) having electrical conductivity which is (a) greater than insulators, but also (b) less than good conductors; and such semiconductor substance may be used as a base material for dies that hold microelectronic circuits and/or electronic devices. Semiconductors may include elements such as silicon and germanium; and compounds such as silicon carbide, aluminum phosphide, gallium arsenide, and indium antimonide. The term “semiconductor” may include any one or a combination of elemental semiconductor(s) and/or compound semiconductor(s), as well as strained semiconductors (e.g., semiconductors under tension or compression). The present invention may utilize indirect bandgap semiconductors (e.g., Si, Ge, and SiC) and/or direct bandgap semiconductors (e.g., GaAs, GaN, and InP).

The term “substrate” as used herein may include any item having a surface, which is intended for processing. The substrate may be constructed, for example, as a semiconductor wafer containing an array of dies. However, the term “substrate” is not limited to items made from semiconductor materials; and may include carriers used for packaging semiconductor dies.

The term “subtractive”, as in “subtractive step” or “subtractive process”, as used herein, may include a step or process of selective removal of material from a bulk article or from a raw aggregate of materials (e.g., from bonded particulate matter), in order to form an article of a desired shape or structure.

Some embodiments of the present invention may take the form of an entirely hardware embodiment, an entirely software embodiment, or an embodiment including both hardware and software elements. Some embodiments of the present invention may be implemented in software, firmware, resident software, microcode, an application which may be downloaded and/or installed by a user, an application which may run in a browser, a client-side application, a server-side application, a client-server application, or the like. Some embodiments of the present invention may take the form of a computer program product accessible from a computer-usable or computer-readable medium providing program code for use by or in connection with a computer or any instruction execution system. For example, a computer-usable or computer-readable medium may be or may include any apparatus that can contain, store, communicate, propagate, or transport the program for use by or in connection with the instruction execution system or device. Some embodiments of the present invention may be implemented, for example, using a machine-readable medium or article which may store an instruction or a set of instructions that, if executed by a machine, cause the machine (e.g., a computer or an electronic device) to perform a method and/or operations described herein.

Some embodiments of the present invention may include or may utilize, for example, a processor, a central processing unit (CPU), a digital signal processor (DSP), a controller, an integrated circuit (IC), a memory unit, a storage unit, input units, output units, wired and/or wireless communication units, an operating system, and other suitable hardware components and/or software modules.

Functions, operations, components and/or features described herein with reference to one or more embodiments of the present invention, may be combined with, or may be utilized in combination with, one or more other functions, operations, components and/or features described herein with reference to one or more other embodiments of the present invention.

While certain features of the present invention have been illustrated and described herein, many modifications, substitutions, changes, and equivalents may occur to those skilled in the art. Accordingly, the claims are intended to cover all such modifications, substitutions, changes, and equivalents.

What is claimed is:

1. A device comprising:
a first 3D-printing head to selectively discharge conductive 3D-printing material;
a second 3D-printing head to selectively discharge insulating 3D-printing material;
a processor to control operations of the first and second 3D-printing heads based on a computer-aided design (CAD) scheme describing a multi-layer printed circuit board (PCB) intended for 3D-printing.

2. The device of claim 1, wherein the first and second 3D-printing heads are to 3D-print a functional resistor.

3. The device of claim 1, wherein the first and second 3D-printing heads are to 3D-print a functional heat-sink.

4. The device of claim 1, wherein the first 3D-printing head is to discharge resin impregnated with highly-conductive metallic nano-particles.

5. The device of claim 1, wherein the first 3D-printing head that is able to discharge the conductive 3D-printing material is associated with at least a first and a second 3D-printing nozzles;
wherein the first 3D-printing nozzle is to discharge the conductive 3D-printing material through a first nozzle aperture having a first diameter;
wherein the second 3D-printing nozzle is to discharge the conductive 3D-printing material through a second nozzle aperture having a second, different, diameter;
wherein the device comprises an on-the-fly switching module to selectively activate, during a 3D-printing process, one of the first and second 3D-printing nozzles.

6. The device of claim 1, further comprising:
a laser source to emit a targeted laser beam,
wherein the laser source follows the 3D-printing heads and emits the targeted laser beam for curing just-dispensed 3D-printed materials.

7. The device of claim 1, further comprising:
a filled via 3D-printing module to 3D-print a structure that functionally corresponds to an inter-layer filled via which is filled with at least one of: (a) a 3D-printed electrically-conductive material, (b) a 3D-printed thermally-conductive material;
wherein the filled via 3D-printing module is to fill at least 90 percent of a volume of said structure, using 3D-printing, with a 3D-printed material.

8. The device of claim 1, further comprising:
a drill-free 3D-printing module to 3D-print, in a drill-free and ablation-free process and without a subtractive process, a multi-layer structure that functionally corresponds to an inter-layer via.

9. The device of claim 1, further comprising:
an impedance reference 3D-printing module to 3D-print a dedicated region of 3D-printed material as reference ground for 3D-printed impedance-controlled trace.

10. The device of claim 1, further comprising:
an impedance reference 3D-printing module to 3D-print a dedicated region of 3D-printed material as reference power for 3D-printed impedance-controlled trace.

11. The device of claim 1, further comprising:
an impedance reference 3D-printing module to 3D-print a dedicated region of 3D-printed material as reference power for 3D-printed impedance-controlled trace, wherein the 3D-printed reference power follows the 3D-printed impedance-controlled trace and is 3D-printed over the 3D-printed impedance-controlled trace.

12. The device of claim 1, further comprising:
an on-the-fly Automatic Optical Inspection (AOI) module (A) to capture an image of a 3D-printed conductive trace during an ongoing 3D-printing session; (B) to compare the captured image to a reference indicating a required structure of the 3D-printed conductive trace; (C) based on the comparison, to identify a fracture in the 3D-printed conductive trace; (D) to trigger a corrective 3D-printing operation to 3D-print again, correctly, at least a region comprising said fracture.

13. The device of claim 1, further comprising:
a soldermask 3D-printing module to 3D-print a soldermask on a 3D-printed PCB;
a 3D-printing ordering module to cause the device
(A) to 3D-print a first region of the 3D-printed PCB,
(B) to 3D-print soldermask onto said first region of the 3D-printed PCB,
(C) to wait for said soldermask to cure at said first region.

14. The device of claim 1, comprising:
a heat sink 3D-printing module to 3D-print a thermally-conductive heat sink integrated in a pre-defined region of a 3D-printed PCB being 3D-printed.

15. The device of claim 1, comprising:
an embedded COB component 3D-printing module, to 3D-print a 3D-printed PCB having a fully-buried 3D-printed Chip-On-Board (COB) component.

16. The device of claim 1, comprising:
a rigidity/flexibility modifier to 3D-print a PCB having a gradually-changing level of rigidity.

17. The device of claim 1, comprising:
a non-parallel layer 3D-printing module to 3D-print: (A) a first 3D-printed conductive layer, and (B) a second, neighboring, non-parallel, 3D-printed conductive layer;
a compensating module to compensate for non-parallelism of the first and second 3D-printed conductive layers by modifying a thickness of a 3D-printed dielectric material between said first and second 3D-printed conductive layers.

18. The device of claim 1, further comprising:
an inter-layer transition placement module to enhance a distribution of inter-layer transitions to be 3D-printed, based on a target overall thickness of an intended 3D-printed PCB.

19. The device of claim 1, further comprising:
an Impedance-Controlled Via 3D-printing module to 3D-print an inter-layer via as an extension of a 3D-printed conductive trace;
wherein the 3D-printed inter-layer via has a shielding identical to a shielding of said 3D-printed conductive trace.

20. The device of claim 1, comprising:
a pause-and-resume 3D-printing controller,
(A) to pause a 3D-printing process of a PCB being 3D-printed,
(B) to wait until a COB/SMT component is assembled onto an already-3D-printed portion of the PCB,
(C) to resume the 3D-printing process of said PCB on top of the COB/SMT that was 3D-printed.
